(19) United States
(12) Patent Application Publication
(10) Pub. No.: US 2026/0214912 A1
(43) Pub. Date: Jul. 23, 2026

(54) SEMICONDUCTOR DEVICE

(71) Applicant: SK hynix Inc., Icheon-si Gyeonggi-do (KR)

(72) Inventor: Ki Hong LEE, Suwon-si Gyeonggi-do (KR)

(73) Assignee: SK hynix Inc., Icheon-si Gyeonggi-do (KR)

(21) Appl. No.: 19/569,693

(22) Filed: Mar. 17, 2026

Related U.S. Application Data
(63) Continuation-in-part of application No. 18/756,056, filed on Jun. 27, 2024.
Application No. 18/756,056 is a continuation of application No. 17/721,932, filed on Apr. 15, 2022, now Pat. No. 12,048,168.
Application No. 17/721,932 is a continuation of application No. 16/588,162, filed on Sep. 30, 2019, now Pat. No. 11,342,342.
Application No. 16/588,162 is a continuation of application No. 15/170,285, filed on Jun. 1, 2016, now Pat. No. 10,468,422.

(30) Foreign Application Priority Data
Jan. 18, 2016 (KR) 10-2016-0006075

(51) Int. Cl. H10B 69/00; H10B 41/27; H10B 41/41; H10B 41/50; H10B 43/27; H10B 43/40; H10B 43/50; H10D 1/00; H10W 20/41; H10W 20/42

(52) U.S. Cl. CPC H10B 69/00; H10B 41/27; H10B 41/41; H10B 41/50; H10B 43/27; H10B 43/40; H10B 43/50; H10D 1/00; H10W 20/42; H10W 20/435

(57) ABSTRACT

A semiconductor device may include a source layer having a groove in an upper surface thereof; a conductive pattern disposed in the groove; a stack structure disposed over the source layer and the conductive pattern, the stack structure comprising at least one first select line, a plurality of word lines and at least one second select line; a channel layer extending through the stack structure, the channel layer being in contact with the source layer; and a source pick-up line extending through the stack structure and the conductive pattern to contact the source layer, wherein a vertical length of the channel layer is greater than a vertical length of the source pick-up line.

### CROSS-REFERENCE TO RELATED APPLICATION

The present application is a continuation-in-part application of U.S. patent application Ser. No. 18/756,056, filed on Jun. 27, 2024, which is a continuation application of U.S. patent application Ser. No. 17/721,932, filed on Apr. 15, 2022, which is a continuation application of U.S. patent application Ser. No. 16/588,162, filed on Sep. 30, 2019, which is a continuation application of U.S. patent application Ser. No. 15/170,285, filed on Jun. 1, 2016, which claims priority under 35 U.S.C. § 119(a) to Korean patent application number 10-2016-0006075 filed on Jan. 18, 2016, in the Korean Intellectual Property Office, the entire contents of which applications are incorporated herein by reference.

### BACKGROUND

### 1. Technical Field

An aspect of the present disclosure generally relates to an electronic device and a manufacturing method thereof, and more particularly to a three-dimensional semiconductor device and a manufacturing method thereof.

### 2. Related Art

Nonvolatile memory devices are memory devices that retain their stored data even in the absence of a power supply. Traditional two-dimensional nonvolatile memory devices have reached the limits of their memory capacity due to structural and material issues. These limits have increased the interest of the semiconductor industry in a three-dimensional nonvolatile memory device in which memory cells are vertically stacked over a substrate.

In an example of three-dimensional nonvolatile memory device, a stacked structure may be formed by alternately stacking conductive layers and insulating layers, and a channel layer may be formed to pass through the stacked structure, thereby simultaneously forming a plurality of memory cells.

### SUMMARY

Embodiments provide a manufacturing method of a semiconductor device that is easily manufactured and has improved characteristics.

According to an aspect of the present disclosure, a semiconductor device may include a source layer having a groove in an upper surface thereof; a conductive pattern disposed in the groove; a stack structure disposed over the source layer and the conductive pattern, the stack structure comprising at least one first select line, a plurality of word lines and at least one second select line; a channel layer extending through the stack structure, the channel layer being in contact with the source layer; and a source pick-up line extending through the stack structure and the conductive pattern to contact the source layer, wherein a vertical length of the channel layer is greater than a vertical length of the source pick-up line.

According to an aspect of the present disclosure, a semiconductor device may include a source layer having a groove in an upper surface thereof; a stack structure disposed over the source layer, wherein the stack structure includes at least one first select line, word lines and at least one second select line; a channel layer extending through the stack structure, the channel layer being in contact with the source layer; and a source pick-up line extending through the stack structure and into the groove to contact the source layer, wherein the channel layer has a greater height than the source pick-up line.

### BRIEF DESCRIPTION OF THE DRAWINGS

FIGS. 1A to 1D are sectional views illustrating example structures of a semiconductor device according to embodiments of the present disclosure.

FIGS. 2A to 2G are sectional views illustrating an example manufacturing method of a semiconductor device according to an embodiment of the present disclosure.

FIGS. 3A to 3I are sectional views illustrating an example manufacturing method of a semiconductor device according to an embodiment of the present disclosure.

FIG. 4 is a sectional view illustrating an example manufacturing method of a semiconductor device according to an embodiment of the present disclosure.

FIGS. 5 and 6 are diagrams illustrating example configurations of memory systems according to embodiments of the present disclosure.

FIGS. 7 and 8 are diagrams illustrating example configurations of computing systems according to embodiments of the present disclosure.

FIG. 9 is a diagram illustrating the structure of a semiconductor device in accordance with an embodiment.

FIG. 10 is a diagram illustrating the structure of a semiconductor device in accordance with an embodiment.

FIG. 11 is a diagram illustrating the structure of a semiconductor device in accordance with an embodiment.

FIG. 12A-12C is a diagram illustrating the structure of a semiconductor device in accordance with an embodiment.

FIG. 13A-13D is a diagram illustrating the structure of a semiconductor device in accordance with an embodiment.

FIGS. 14A and 14B are diagrams illustrating the structure of a semiconductor device in accordance with an embodiment. FIG. 14B is a cross-sectional view taken along line A A′ of FIG. 14A.

FIGS. 15A to 15D are diagrams illustrating the structure of a semiconductor device in accordance with an embodiment. FIG. 15C is a cross-sectional view taken along line B-B′ of FIG. 15A. FIG. 15D is a modified example of FIG. 15C and is a cross-sectional view taken along line C-C′ of FIG. 15A.

FIGS. 16A and 16B are diagrams illustrating the structure of a semiconductor device in accordance with an embodiment.

FIGS. 17A and 17B are diagrams illustrating the structure of a semiconductor device in accordance with an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

Example embodiments of the present disclosure will be described with reference to the accompanying drawings. The example embodiments of the present disclosure may, however, be embodied in many different forms and should not be construed as limited to the example embodiments set forth herein. Rather, the example embodiments are provided so that disclosure of the present disclosure will be thorough and complete, and will fully convey the scope of the present disclosure to those skilled in the art. The features of example embodiments of the present disclosure may be employed in various and numerous embodiments without departing from the scope of the present disclosure. In the drawings, the size and relative sizes of layers and areas may be exaggerated for clarity. The drawings are not to scale. Like reference numerals refer to like elements throughout.

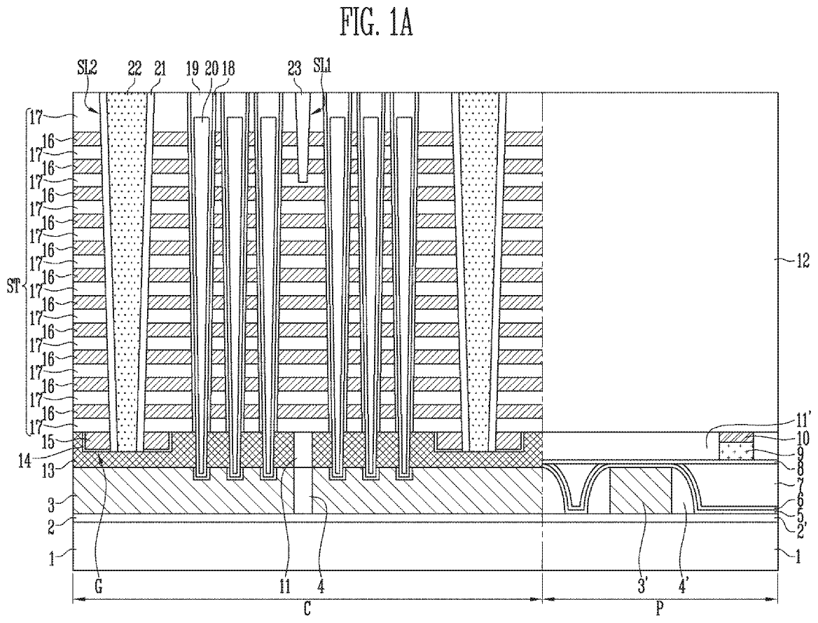

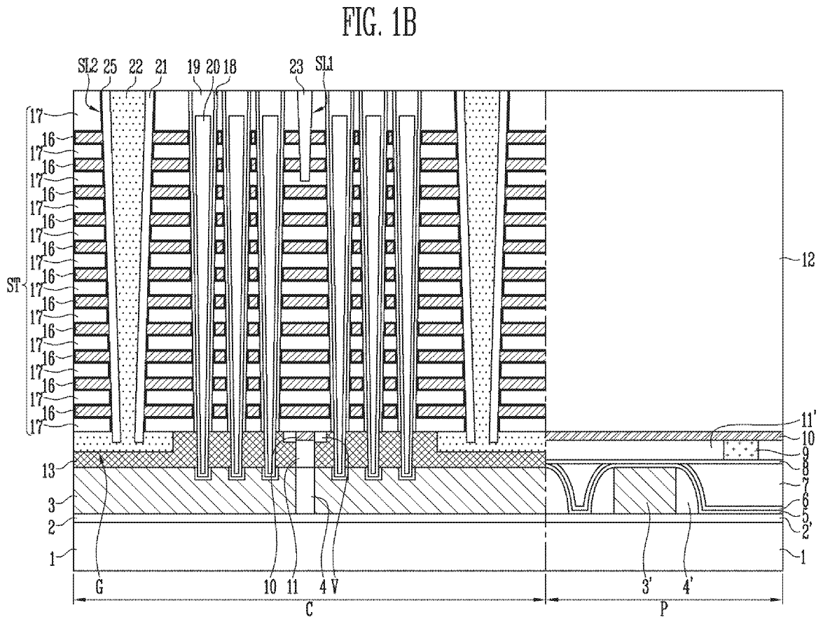

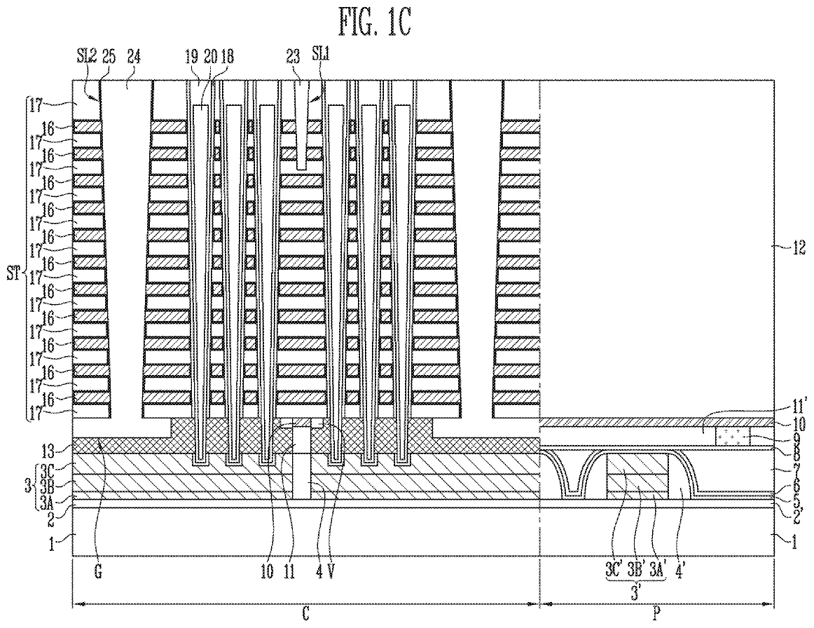

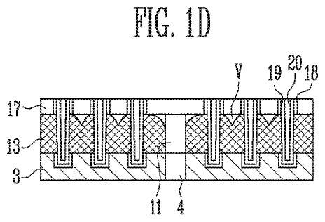

FIGS. 1A to 1D are sectional views illustrating example structures of semiconductor devices according to embodiments of the present disclosure.

Referring to FIG. 1A, the semiconductor device according to an embodiment of the present disclosure may include a cell region C in which a cell array is positioned and a peripheral region P in which a driving circuit for driving the cell array is positioned. Here, the cell region C and the peripheral region P may be positioned at the same level over a substrate 1. Alternatively, the cell region C and the peripheral region P may be positioned at different levels from one another. Although it is illustrated that the cell region C and the peripheral region P are positioned at the same level, the peripheral region P may be positioned under or over the cell region C.

First, the cell region C will be described. A first source layer 3 may be positioned in the cell region C of the substrate 1. The first source layer 3 may include a conductive layer, and may be formed of the same material as a gate electrode 3′ of a transistor positioned in the peripheral region P. In order to insulate the substrate 1 and the first source layer 3 from each other, a first insulating layer 2 may be interposed between the substrate 1 and the first source layer 3. Here, the first insulating layer 2 may extend up to the peripheral region P to be connected to a gate insulating layer 2′ of the transistor. That is, the first insulating layer 2 and the gate insulating layer 2′ may be formed as a single layer. Here, the first source layer 3 and the gate electrode 3′ may be doped polysilicon layers, and the first insulating layer 2 and the gate insulating layer 2′ may be oxide layers.

The first source layer 3 may be separated into a plurality of patterns by a second insulating layer 4. The second insulating layer 4 may be formed of the same material as a spacer 4′ formed on a sidewall of the gate electrode 3′.

A second source layer 13 may be positioned on the first source layer 3, and may be in direct contact with an upper surface of the first source layer 3. The second source layer 13 may has at least one groove G on an upper surface thereof. An oxide layer 14 may be formed on a surface of the groove G, and the groove G may be filled with a conductive pattern 15. Here, the conductive pattern 15 may be formed of the same material as a conductive layer 16. The second source layer 13 may be separated into a plurality of patterns by a third insulating layer 11. The third insulating layer 11 may be formed of the same material as a second interlayer insulating layer 11′ formed in the peripheral region P.

The first source layer 3 and the second source layer 13 may be electrically connected to each other, and may include silicon. For example, the first source layer 3 may be a polysilicon layer formed through a deposition process, and the second source layer 13 may be a polysilicon layer formed through a selective growth process.

A stack structure ST may be positioned over the second source layer 13, and may include conductive layers 16 and insulating layers 17, which are alternately stacked. Here, the conductive layers 16 may contain a metal such as tungsten, and the insulating layers 17 may contain oxides and/or nitrides. At least one of conductive layers 16 disposed at upper levels (e.g., the uppermost conductive layer 16) may be an upper select line. At least one of the conductive layers 16 disposed at lower levels (e.g., the lowermost conductive layer 16) may be a lower select line. The other conductive layers 16 may be word lines.

A plurality of channel layers 19 may pass through the stack structure ST, and may be in contact with the second source layer 13. Here, the plurality of channel layers 19 may extend down to the first source layer 3 by completely passing through the second source layer 13, and may be in contact with the first source layer 3.

The channel layers 19 may include a semiconductor material such as silicon (Si) or germanium (Ge). Each of the channel layers 19 may include a gap-fill insulating layer 20 formed in an open central region thereof. Also, a memory layer 18 may surround sidewalls of each of the channel layers. Here, the memory layer 18 may include a tunnel insulating layer, a data storage layer, and a charge blocking layer. Here, the data storage layer may be a layer that stores electric charges such as electrons. Examples of the data storage layer may include a silicon material, a nitride material, a charge trapping material, a phase-change material, a ferroelectric material, a nano-dot material, etc.

A first slit SL1 may be formed with a depth such that it extends to a certain depth from the surface of the stack structure ST. For example, the first slit SL1 may be formed with a depth such that it passes through conductive layers 16 that are formed to be used for upper select lines. A slit insulating layer 23 may be positioned in the first slit SL1, and the conductive layers 16 for upper select lines, which are positioned at the same level, may be insulated from each other by the slit insulating layer 23.

A second slit SL2 may have a depth such that it exposes the groove G of the second source layer 13 by passing through the stack structure ST. A source pick-up line 22 may be positioned in the second slit SL2 and the groove G, and may be in contact with the second source layer 13. In addition, an insulative spacer 21 may surround sidewalls of the source pick-up line 22 to insulate the source pick-up line 22 and the conductive layers 16 from each other.

A driving circuit may be positioned in the peripheral region P of the substrate 1. The driving circuit may include a transistor. The transistor may be positioned at the substantially same level as the first source layer 3, and may be formed of the same material as the first source layer 3. A first etch stop layer 5 and 6, a first interlayer insulating layer 7, and a second etch stop layer 8 may be positioned over the gate electrode 3′ and spacer 4′ of the transistor. Here, the first etch stop layer 5 and 6 may be a layer that is formed by stacking an oxide layer 5 and a nitride layer 6, and the second etch stop layer 8 may contain nitrides. In addition, the second interlayer insulating layer 11′ and a third interlayer insulating layer 12 may be stacked on the second etch stop layer 8, and a resistor pattern 9 and a hard mask 10 may be positioned in the second interlayer insulating layer 11.

Referring to FIG. 1B, the source pick-up line 22 may be positioned in the second slit SL2 and the groove G. The source pick-up line 22 may include a first region positioned in the groove G and a second region positioned in the second slit SL2, and the second region may have a narrower width than the first region. Here, the source pick-up line 22 may be in direct contact with the second source layer 13, and therefore the first source layer 3, the second source layer 13, and the source pick-up line 22 may be electrically connected to each other.

At least a portion of the hard mask 10 may remain on the third insulating layer 11 of the cell region C, and a void V may exist around the hard mask 10. In addition, a memory layer 25 may be additionally formed between the conductive layers 16 and the memory layers 18. The additionally formed memory layer 25 may be a charge blocking layer.

The rest of the structure may be the same as described with reference to FIG. 1A.

Referring to FIG. 1C, the first slit insulating layer 23 may be formed in the first slit SL1, and a second slit insulating layer 24 may be formed in the second slit SL2 and the groove G. Here, the second slit insulating layer 24 may be in contact with the second source layer 13.

The first source layer 3 may include a polysilicon layer 3A, a metal layer 3B, and a polysilicon layer 3C, and the metal layer 3B may include tungsten. The gate electrode 3′ may include a polysilicon layer 3A′, a metal layer 3B′, and a polysilicon layer 3C′, and the metal layer 3B′ may include tungsten. Thus, although a source pick-up line containing a metal is not separately formed, a source resistance can be decreased by the metal layer 3B included in the first source layer 3. Although not illustrated, a source pick-up contact plug may be connected to the metal layer 3B. In addition, the resistance of the gate electrode 3′ can be decreased by the metal layer 3B′. The rest of the structure may be the same as described with reference to FIG. 1A or 1B.

FIG. 1D illustrates an enlargement of the second source layer 13 of FIG. 1A to discuss an embodiment in which the second source layer 13 includes an uneven upper surface. In this case, at least one void V may exist between the second source layer 13 and the stack structure ST. Here, the void V refers to an empty space in which any material layer does not exist. Like FIG. 1D, in the sectional views of FIGS. 1B and 1C, the second source layer 13 may include an uneven upper surface, and at least one void V may exist between the second source layer 13 and the stack structure ST.

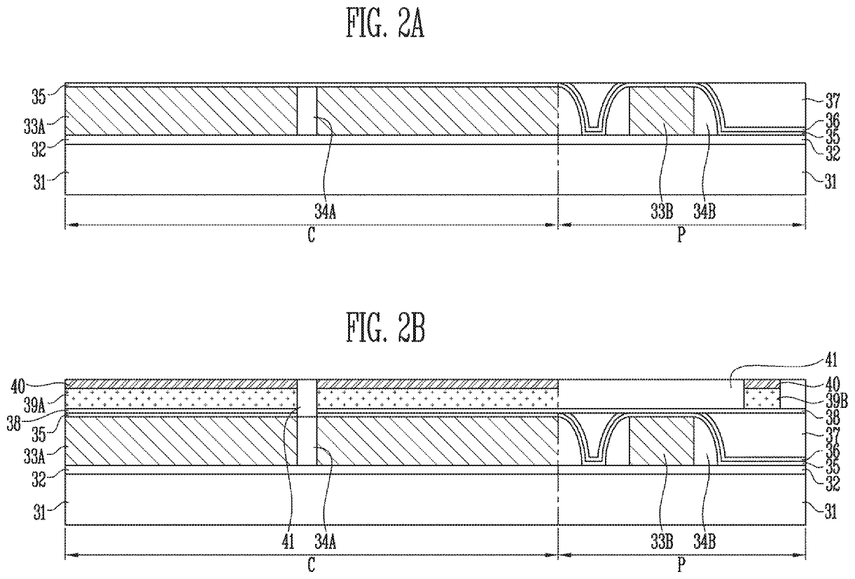

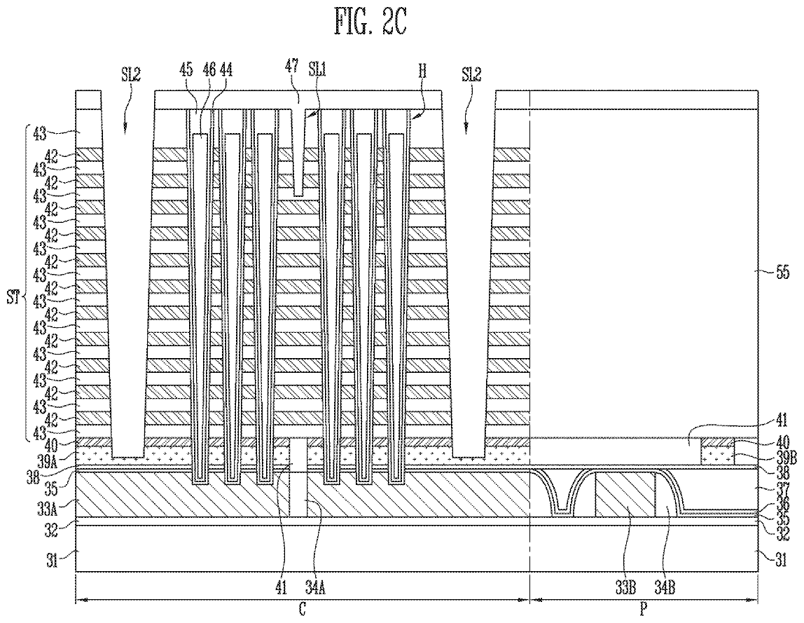

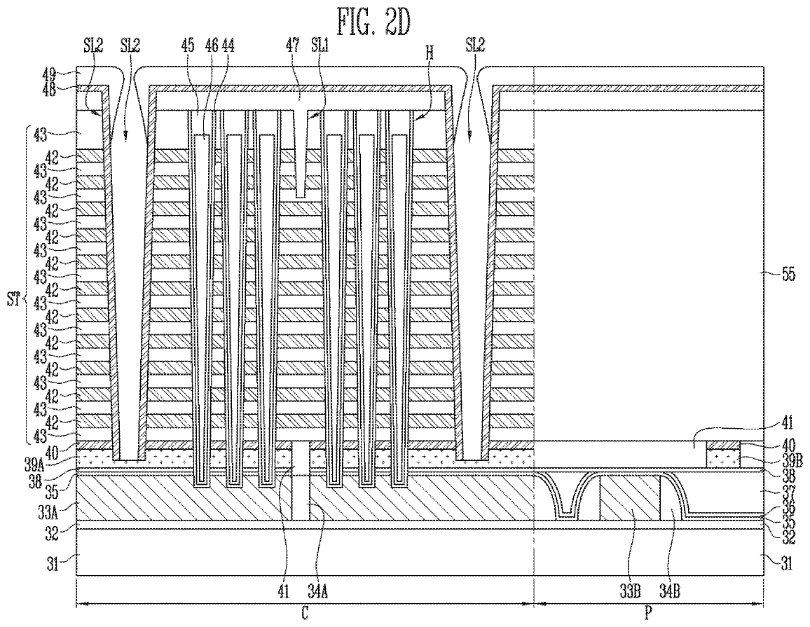

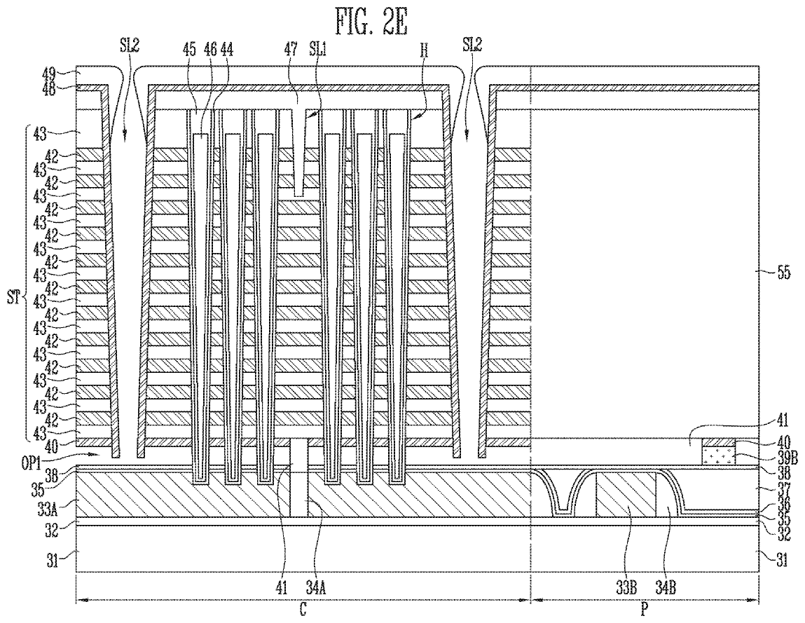

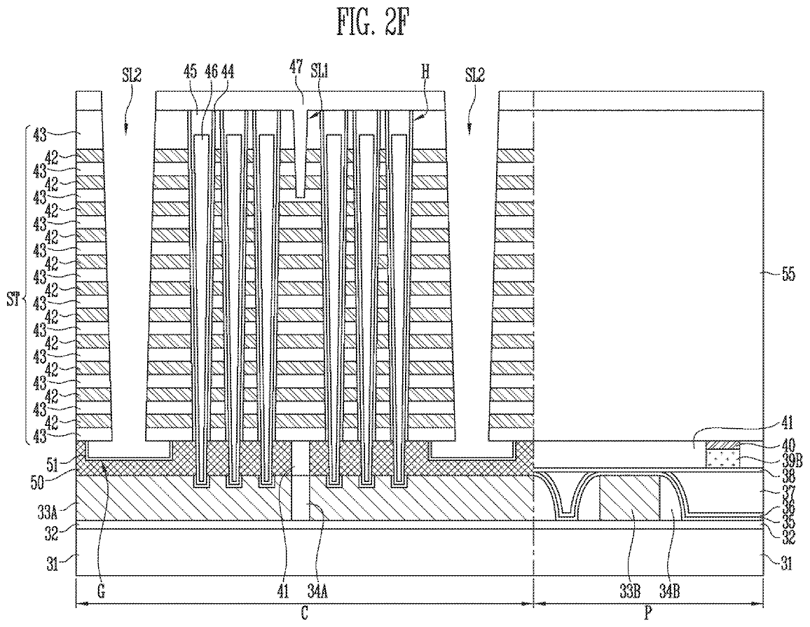

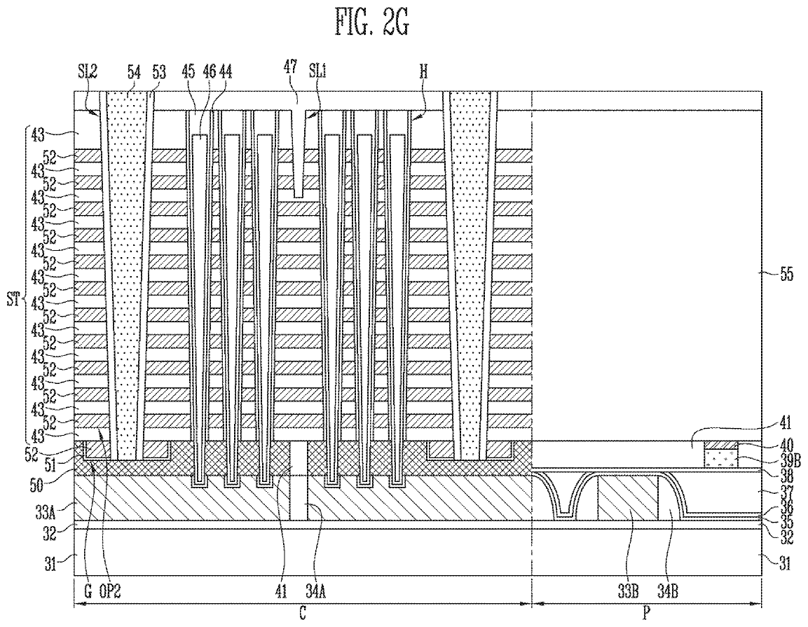

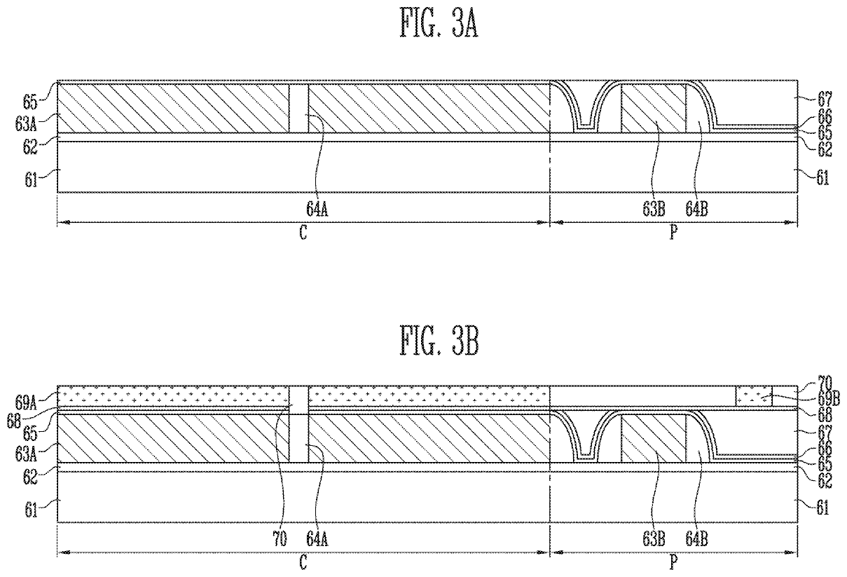

FIGS. 2A to 2G are sectional views illustrating an example manufacturing method of a semiconductor device according to an embodiment of the present disclosure.

Referring to FIG. 2A, a first insulating layer 32 and a first conductive layer may be formed on a substrate 31 including a cell region C and a peripheral region P. Subsequently, the first conductive layer may be patterned, thereby forming a first source layer 33A of the cell region C and a gate electrode 33B of the peripheral region P. Subsequently, an insulating material may be formed along the entire surface of the resultant structure in which the first source layer 33A and the gate electrode 33B have been formed, and then a blanket etching process is performed to the insulating material. Accordingly, a second insulating layer 34A and a space spacer 34B of the gate electrode 33B may be formed which separate the first source layer 33A of the cell region C into a plurality of patterns.

Subsequently, a first etch stop layer 35 and 36 and a first interlayer insulating layer 37 may be formed along the entire surface of the resultant structure. Here, the first etch stop layer 35 and 36 may be a layer that is formed by stacking an oxide layer 35 and a nitride layer 36, and the first interlayer insulating layer 37 may be a high density plasma (HDP) oxide layer. Subsequently, a planarization process may be performed to planarize the first interlayer insulating layer 37 until the first etch stop layer 35 and 36 is exposed. For example, a chemical mechanical polishing (CMP) may be performed until the first etch stop layer 35 and 36 is exposed, and the exposed nitride layer 36 may be etched back. Accordingly, the oxide layer 35 may be exposed on the first source layer 33A and on the gate electrode 33B.

Referring to FIG. 2B, a second etch stop layer 38, a second conductive layer, and a hard mask layer may be formed on the resultant structure. Here, the second conductive layer may be a polysilicon layer, and the hard mask layer may be a nitride layer formed through a low pressure chemical vapor deposition (LP-CVD).

Subsequently, the hard mask layer and the second conductive layer may be patterned, thereby forming a second source sacrificial layer 39A of the cell region C and a resistor pattern 39B of the peripheral region P. Here, the resistor pattern 39B may be positioned such that it is not overlapped with a transistor. In addition, a hard mask pattern 40 may remain over the second source sacrificial layer 39A and the resistor pattern 39B.

Subsequently, an insulating material may be formed on the entire surface of the resultant structure, and then the insulating material may be planarized until the hard mask pattern 40 is exposed, thereby forming a second interlayer insulating layer 41.

Referring to FIG. 2C, a stack structure ST may be formed over the resultant structure in which the second interlayer insulating layer 41 has been formed. Here, the stack structure ST may include first material layers 42 and second material layers 43, which are alternately stacked. The first material layers 42 may include a material having a high etching selection ratio with respect to the second material layers 43. For example, the first material layers 42 may be sacrificial layers containing nitrides, and the second material layers 43 may be insulating layers containing oxides. The first material layers 42 may be conductive layers containing polysilicon materials, and the second material layers 43 may be insulating layers containing oxides. The first material layers 42 may be conductive layers containing a dopant, and the second material layers 43 may be sacrificial layers containing no dopant. The first material layers 42 may be first sacrificial layers containing nitrides, and the second material layers 43 may be second sacrificial layers containing oxides.

For reference, the stack structure ST may be formed in both the cell region C and the peripheral region P, or may be formed in only the cell region C. For example, after the stack structure ST is formed over the substrate 31 including the cell region C and the peripheral region P, the stack structure ST formed in the peripheral region P may be removed, and a third interlayer insulating layer 55 may be formed.

Subsequently, holes H passing through the stack structure ST of the cell region C may be formed. Here, the holes H may completely pass through the stack structure ST and extend down to the first source layer 33A or the second source sacrificial layer 39A. For example, each of the holes H may completely pass through the stack structure ST, the second source sacrificial layer 39A, the second etch stop layer 38, and the first etch stop layer 35, and may be formed with a depth such that it extends to a certain depth from the surface of the first source layer 33A.

Subsequently, a channel layer 45 and a memory layer 44 surrounding the channel layer 45 may be formed in each of the holes H. Here, the channel layer 45 may include a semiconductor material such as silicon (Si) or germanium (Ge). The channel layer 45 may include a gap-fill insulating layer 46 formed in an opened central region thereof. The memory layer 44 may include a tunnel insulating layer, a data storage layer, and a charge blocking layer. The data storage layer may contain a silicon-based material, a nitride material, a phase-change material, a ferroelectric material, or a nano-dot material.

Subsequently, a first slit SL1 may be formed such that it extends to a certain depth from the surface of the stack structure ST. For example, the first slit SL1 may be formed with a depth such that it passes through the first material layers 42 for upper select lines. Subsequently, a slit insulating layer 47 may be formed in the first slit SL1. The slit insulating layer 47 may be formed over the stack structure ST.

Subsequently, second slits SL2 may be formed to expose the second source sacrificial layer 39A by passing through the stack structure ST. When the second slits SL2 are formed, at least a portion of the second source sacrificial layer 39A may be etched. The first material layers 42 and the second source sacrificial layer 39A are exposed through the second slits SL2.

Referring to FIG. 2D, a protective layer 48 may be formed in the second slits SL2, and a mask pattern 49 may then be formed such that it surrounds upper inner walls of the second slits SL2. Here, the protective layer 48 may be formed with a uniform thickness along inner surfaces of the second slits SL2 by using a method having a relatively excellent step coverage, and the mask pattern 49 may be formed in an overhang shape in only openings of the second slits SL2 by using a method having a relatively poor step coverage. For example, the protective layer 48 may be a nitride layer formed through a low pressure chemical vapor deposition (LP-CVD), and the mask pattern 49 may be a nitride layer formed through a physical vapor deposition (PVD).

Subsequently, the protective layer 48 formed on a bottom surface of the second slit SL2 may be etched using the mask pattern 49 as an etching barrier, thereby exposing the second source sacrificial layer 39A.

Referring to FIG. 2E, the second source sacrificial layer 39A may be removed through the second slits SL2, thereby forming a first opening OP1. At this time, the first and second material layers 42 and 43 are protected by the protective layer 48, and thus the second source sacrificial layer 39A can be selectively removed. In addition, the memory layers 44 and the second etch stop layer 38 may be exposed through the first opening OP1.

Referring to FIG. 2F, the exposed memory layers 44 may be removed through the first opening OP1. As a result, the channel layers 45 may be exposed in the first opening OP1. In the process of removing the memory layers 44, the first etch stop layer 35 and the second etch stop layer 38 may be removed together with the memory layers 44, so that the first source layer 33A can be exposed in the first opening OP1. Also, in the process of removing the memory layers 44, the hard mask pattern 40 may be removed together with the memory layers 44, so that the lowermost second material layer 43 can be exposed in the first opening OP1. For reference, in the process of removing the memory layers 44, the protective layer 48 and the mask pattern 49 may be removed together with the memory layers 44. Alternatively, the protective layer 48 and the mask pattern 49 may be removed through a separate process.

Subsequently, a second source layer 50 including a groove G, which is in contact with the channel layer 45 and positioned under the second slit SL2, may be formed in the first opening OP1. Here, the second source layer 50 may be a polysilicon layer formed through selective growth. In this case, since the polysilicon layer is grown from surfaces of the channel layers 45 and the first source layer 33A, the growth of the polysilicon layer at a bottom portion of the second slit SL2 may be lower than the other portions, thereby forming the groove G. Although not illustrated, at least one void, as described with reference to FIG. 1D, may be formed between the second source layer 50 and the stack structure ST.

Subsequently, an oxide layer 51 may be formed in the groove G. For example, at least a part of the source layer 50 exposed through the second slit SL2 may be oxidized by performing an oxidation process such as a wet oxidation process. When the wet oxidation process is used, the second source layer 50 including polysilicon may be selectively oxidized without oxidizing the first material layers 42 containing nitrides. Thus, the oxide layer 51 can be formed in only the groove G.

Referring to FIG. 2G, the first material layers 42 exposed through the second slits SL2 may be removed, thereby forming second openings OP2. The oxide layer 51 formed in the groove G can prevent an etchant from infiltrating into the stack structure ST and damaging the memory layer 44. Thus, the oxide layer 51 can be used as a protective layer when the second openings OP2 are formed.

Subsequently, third conductive layers 52 may be formed in the second openings OP2 and the groove G. Before the third conductive layers 52 are formed, at least a part of a memory layer, e.g., a charge blocking layer may be further formed in the second openings OP2. When the third conductive layers 52 are formed in the second slits SL2, the third conductive layers 52 formed in the second slits SL2 may be removed such that the third conductive layers 52 stacked through the second openings OP2 are insulated from each other.

Subsequently, an insulative spacer 53 may be formed on inner walls of the second slits SL2, and a source pick-up line 54 may then be formed in the second slits SL2. For example, an oxide layer is deposited in the second slits SL2, and an overhang-shaped mask pattern (not illustrated) containing titanium nitride (TiN) is then formed in the opening of the second slit SL2 through physical vapor deposition (PVD). Subsequently, the oxide layer formed on bottom surfaces of the second slits SL2 may be removed by performing an etching process. Accordingly, the insulative spacer 53 can be formed.

Here, the source pick-up line 54 may contain a metal such as titanium nitride (TiN) or tungsten. The third conductive layer 52 formed in the groove G may be electrically connected to the source pick-up line 54 and the second source layer 50.

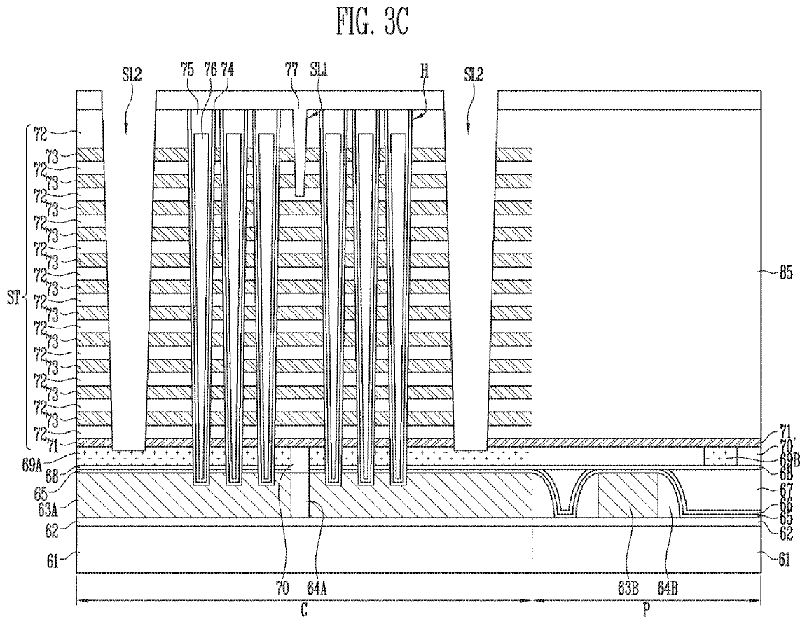

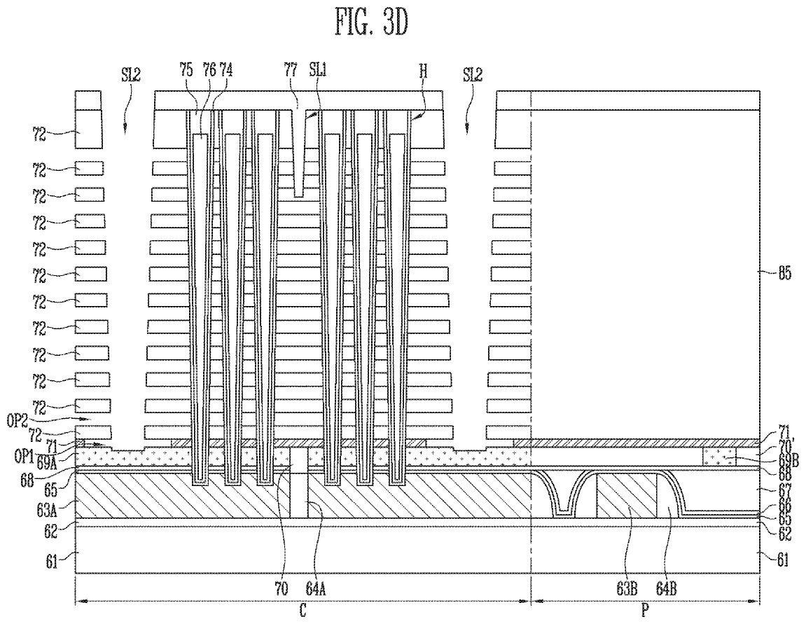

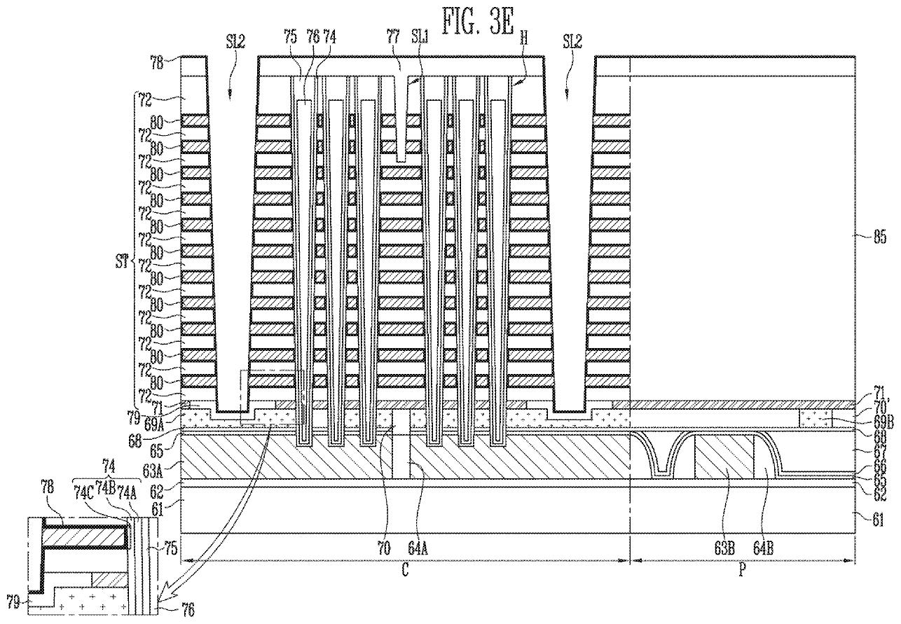

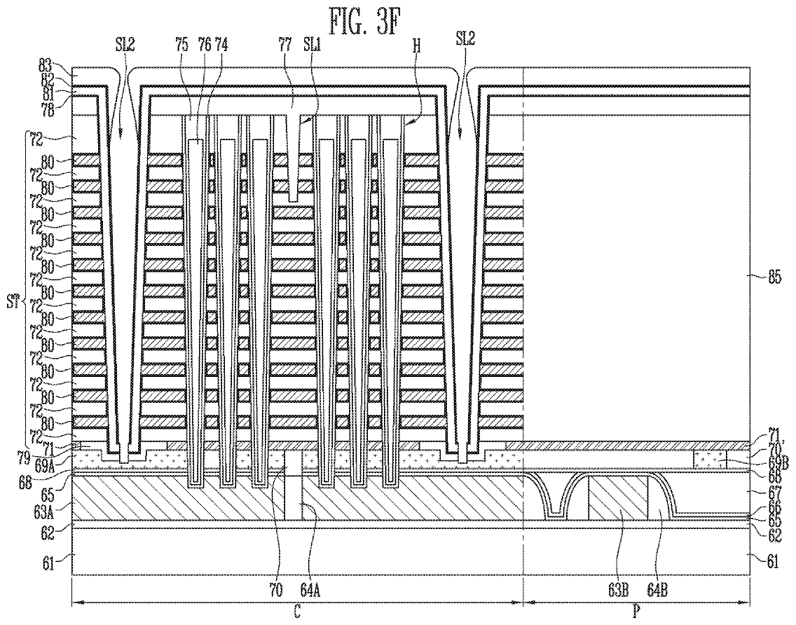

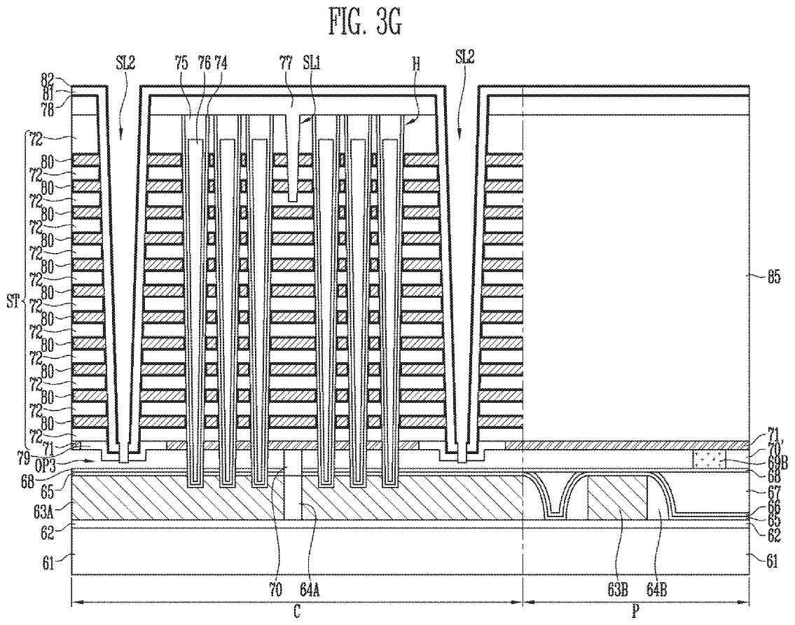

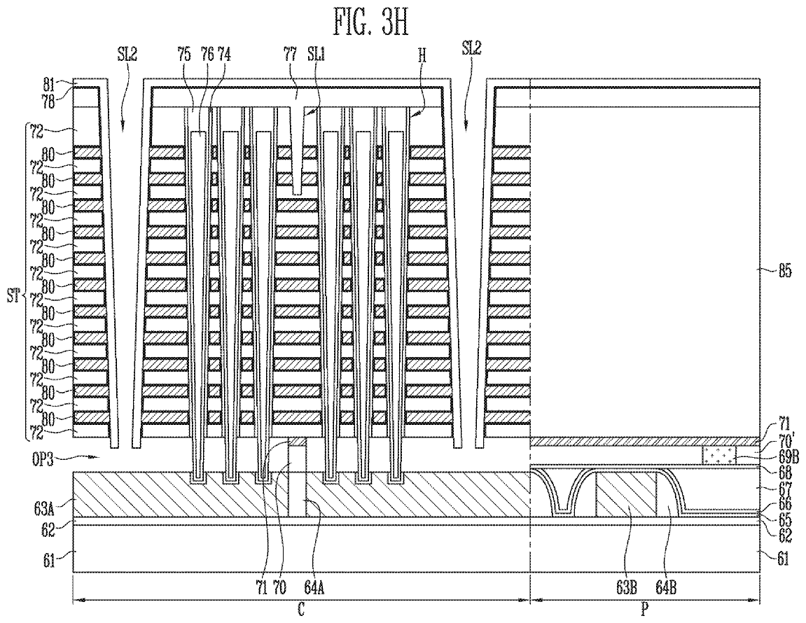

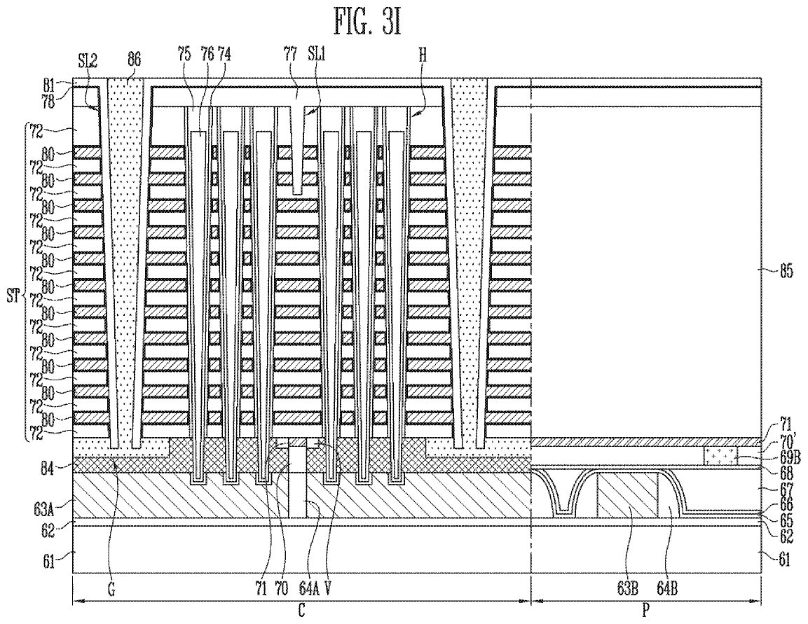

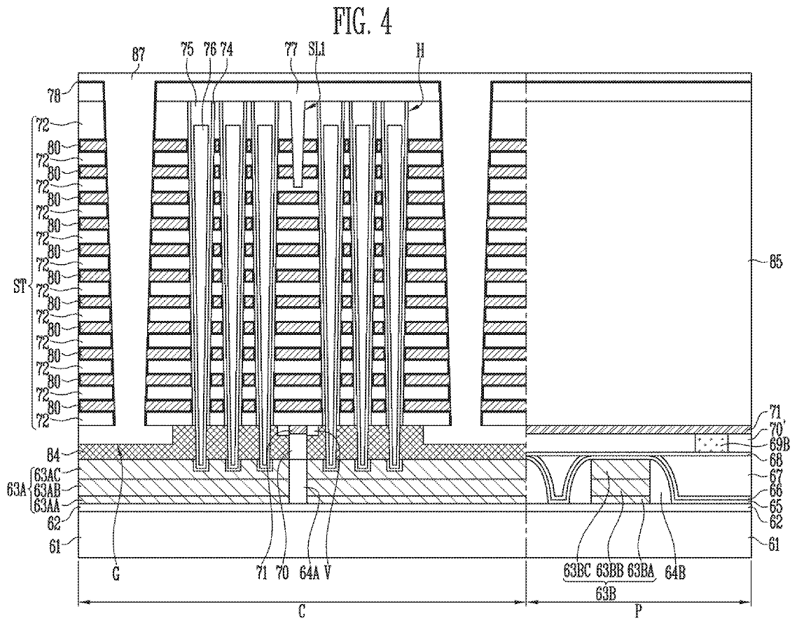

FIGS. 3A to 3I are sectional views illustrating an example manufacturing method of a semiconductor device according to an embodiment of the present disclosure. Hereinafter, any repetitive detailed description will be omitted or simplified.

Referring to FIG. 3A, a first insulating layer 62 and a first conductive layer may be formed on a substrate 61 including a cell region C and a peripheral region P. Subsequently, the first conductive layer may be patterned, thereby forming a first source layer 63A of the cell region C and a gate electrode 63B of the peripheral region P. Subsequently, an insulating material may be formed along the entire surface of the resultant structure in which the first source layer 63A and the gate electrode 63B have been formed, and then an etching process may be conducted. Accordingly, a second insulating layer 64A and a space spacer 64B of the gate electrode 63B, which separate the first source layer 63A of the cell region C into a plurality of patterns, may be formed.

Subsequently, a first etch stop layer 65 and 66 and a first interlayer insulating layer 67 may be formed along the entire surface of the resultant structure. Here, the first etch stop layer 65 and 66 may be a layer that is formed by stacking an oxide layer 65 and a nitride layer 66.

Referring to FIG. 3B, a second etch stop layer 68 and a second conductive layer may be formed on the resultant structure, and the second conductive layer may then be patterned, thereby forming a second source sacrificial layer 69A of the cell region C and a resistor pattern 69B of the peripheral region P. Subsequently, a second interlayer insulating layer 70 may be formed.

Referring to FIG. 3C, a stack structure ST may be formed over the resultant structure in which the second interlayer insulating layer 70 has been formed. Here, the stack structure ST may include a first material layer 71, and second material layers 72 and third material layers 73, which are alternately stacked on the first material layer 71. For reference, the second and third material layers 72 and 73 formed in the peripheral region P may be removed to form a third interlayer insulating layer 85.

The first and third material layers 71 and 73 may include a material having a high etching selection ratio with respect to the second material layers. For example, the first and third material layers 71 and 73 may be sacrificial layers containing nitrides, and the second material layers 72 may be insulating layers containing oxides. The first and third material layers 71 and 73 may be conductive layers including polysilicon materials, and the second material layers 72 may be insulating layers containing oxides. The first and third material layers 71 and 73 may be conductive layers including a dopant, and the second material layers 72 may be sacrificial layers including no dopant. The first and third material layers 71 and 73 may be first sacrificial layers containing nitrides, and the second material layers 72 may be second sacrificial layers containing oxides.

The first material layer 71 and the third material layers 73 may be formed in different manners. For example, the first material layer 71 may be a nitride layer formed through low pressure chemical vapor deposition (LP-CVD), and the third material layers 73 may be nitride layers formed through plasma enhanced chemical vapor deposition (PE-CVD). Thus, the third material layers 73 can have a high etching ratio with respect to the first material layer 71. In addition, the first material layer 71 may be formed with a thinner thickness than the third material layer 73. For example, the first material layer 71 may be formed with a thickness of about 30 to 50 Å.

Subsequently, holes H passing through the stack structure ST may be formed. Here, the holes H may completely pass through the stack structure ST and extend down to the first source layer 63A or the second source sacrificial layer 69A. Subsequently, a channel layer 75 and a memory layer 74 surrounding the channel layer 75 may be formed in each of the holes H. Here, the channel layer 75 may include a semiconductor material such as silicon (Si) or germanium (Ge). The channel layer 75 may include a gap-fill insulating layer 76 formed in an opened central region thereof. The memory layer 74 may include a tunnel insulating layer, a data storage layer, and a charge blocking layer. The data storage layer may contain a silicon-based material, a nitride material, a phase-change material, a ferroelectric material, or a nano-dot material.

Subsequently, a first slit SL1 may be formed such that it extends to a certain depth from the surface of the stack structure ST. For example, the first slit SL1 is formed with a depth such that it passes through the third material layers 73 for upper select lines. Subsequently, a slit insulating layer 77 may be formed in the first slit SL1. The slit insulating layer 77 may be formed over the stack structure ST.

Subsequently, second slits SL2 may be formed to expose the second source sacrificial layer 69A by passing through the stack structure ST. When the second slits SL2 are formed, at least a portion of the second source sacrificial layer 69A may be etched.

Referring to FIG. 3D, the first and third material layers 71 and 73 may be selectively removed through the second slits SL2. Accordingly, a first opening OP1 may be formed in a region in which the first material layer 71 is removed, and second openings OP2 may be formed in regions in which the third material layers 73 are removed. As an example, when the first material 71 is thinner than the third material layers 73, an amount etched from the first material layer 71 may be smaller than an amount etched from the third material layers 73. As another example, when the third material layers 73 have a higher etching ratio than the first material layer 71, the amount etched from the first material layer 71 may be smaller than the amount etched from the third material layers 73. Thus, while a part of the first material layer 71 relatively close to the second slits SL2 is being removed, the other part of the first material layer relatively distant from the second slits SL2 may remain unetched.

Referring to FIG. 3E, a memory layer 78 may be further formed in the second openings OP2. For example, when the memory layer 74 includes a tunnel insulating layer 74A and a data storage layer 74B, a data storage layer 74B may be exposed through the second openings OP2. Thus, at least a part of the data storage layer 74B may be oxidized by through an oxidation process, thereby forming a first charge blocking layer 74C. Subsequently, a second charge blocking layer including a high dielectric constant (high-k) material such as Al₂O₃ may be formed in the second openings OP2. Here, the second charge blocking layer may be the memory layer 78. According to an embodiment, in the process of oxidizing a part of the data storage layer 74B, surfaces of the first material layer 71 and the second source sacrificial layer 69A, which are exposed through the second slit SL2 and the first opening OP1, may be oxidized. Therefore, a first protective layer 79 positioned on the second source sacrificial layer 69A may be formed in the first opening OP1. When the first opening OP1 is not completely filled through the oxidation process, the memory layer 78 may be formed in the first opening OP1.

Subsequently, third conductive layers 80 may be formed in the second openings OP2. Here, the third conductive layers 80 may contain a metal such as tungsten. When the third conductive layer 80 may be formed in the second slit SL2, the third conductive layer 80 formed in the second slit SL2 may be removed such that the third conductive layers 80 stacked through the second openings OP2 are insulated from each other. When the third conductive layer 80 in the second slit SL2 is removed, the first protective layer 79 can prevent damage of the second source sacrificial layer 69A.

Referring to FIG. 3F, a spacer insulating layer, a second protective layer 82, and a mask pattern 83 may be formed in the second slit SL2. Here, the spacer insulating layer may be an oxide layer, the second protective layer 82 may be a nitride layer, and the mask pattern 83 may be a titanium nitride layer or tungsten layer formed through physical vapor deposition (PVD).

Subsequently, the second protective layer 82, the spacer insulating layer, and the first protective layer 79, which are formed on a bottom surface of the second slit SL2, may be etched using the mask pattern 83 as an etching barrier. Accordingly, a spacer 81 may be formed on an inner wall of the second slit SL2, and the second source sacrificial layer 69A may be exposed.

Referring to FIG. 3G, a mask pattern 83 may be removed, and the second source sacrificial layer 69A may then be removed through the second slit SL. Accordingly, a third opening OP3 may be formed, the memory layer 74, the second etch stop layer 68, the first material layer 71, and the first protective layer 79 may be exposed in the third opening OP3.

Referring to FIG. 3H, the memory layer 74 may be removed such that the channel layers 75 are exposed in the third openings OP3. The first and second etch stop layers 65 and 68 may be removed together with the memory layer 74 such that the first source layer 63A is exposed in the third opening OP3. The first material layer 71 and the first protective layer 79 may be removed together with the memory layer 74 such that the second material layer 72 is exposed in the third opening OP3. A portion of the first material layer 71 may remain on the second interlayer insulating pattern 70 of the cell region C. In addition, the second protective layer 82 may be removed together with the memory layer 74 such that the spacer 81 is exposed in the second slit SL2.

Referring to FIG. 3I, a second source layer 84 may be formed in the third opening OP3. The second source layer 84 may have a groove G. The second source layer 84 may be in contact with the channel layer 75 and positioned under the second slit SL2. In this state, a void V may be formed around the second interlayer insulating pattern 70 and the first material layer 71, which remain in the cell region C.

Subsequently, a source pick-up line 86 may be formed in the second slit SL2 and the groove G. The source pick-up line 86 is insulated from the third conductive layers 80 by the spacer 81. The source pick-up line 86 may be electrically connected to the second source layer 84. In addition, the source pick-up line 86 may include a first region formed in the groove G and a second region formed in the second slit SL2. The second region may have a narrower width than the first region.

FIG. 4 is a sectional view illustrating an example manufacturing method of a semiconductor device according to an embodiment of the present disclosure.

Referring to FIG. 4, a first source layer 63A may be a multi-layered layer. A first conductive layer may be formed by stacking a polysilicon layer, a metal layer, and a polysilicon layer. The first source layer 63A and a gate electrode 63B may be formed by patterning the first conductive layer. Accordingly, the first source layer 63A may be formed in which a polysilicon layer 63AA, a metal layer 63AB, and a polysilicon layer 63AC are stacked, and the gate electrode 63B may be formed in which a polysilicon layer 63BA, a metal layer 63BB, and a polysilicon layer 63BC are stacked. The other processes are the same as the processes described with reference to FIGS. 3A to 3H.

Subsequently, a second source layer 84 may be formed in the third opening OP3. The second source layer 84 may have a groove G. The second source layer 84 may be in contact with the channel layer 75 and positioned under the second slit SL2. In this state, a void V may be formed around the second interlayer insulating pattern 70 and the first material layer 71, which remain in the cell region C.

Subsequently, a slit insulating layer 87 may be formed in the second slit SL2 and the groove G. The slit insulating layer 87 may include a first region formed in the groove G and a second region formed in the second slit SL2. The second region may have a narrower width than the first region.

According to this structure, the metal layer 63AB included in the first source layer 63A may serve as the source pick-up line 86. Thus, the process of forming the source pick-up line may be omitted, and the slit insulating layer 87 may be formed in the second slit SL2.

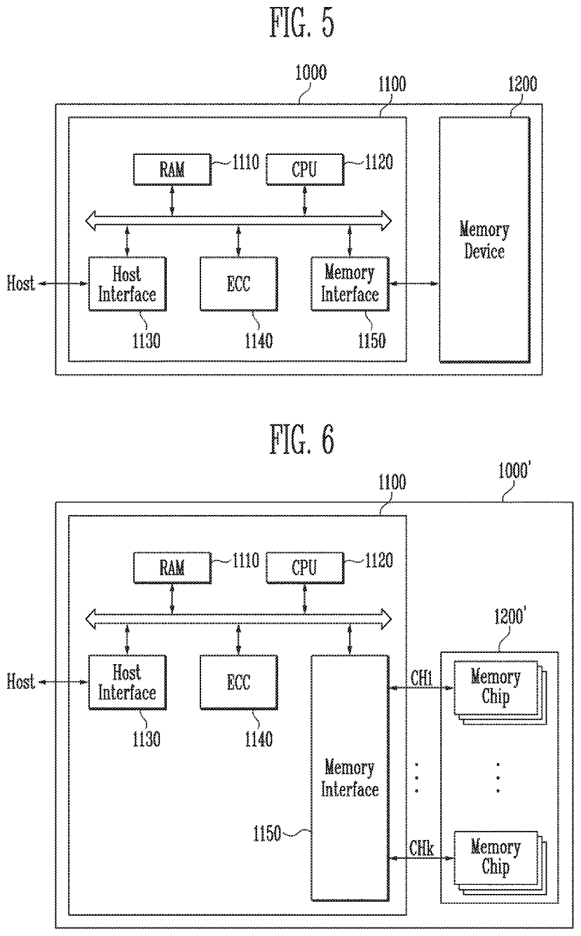

FIG. 5 is a block diagram illustrating an example configuration of a memory system according to an embodiment of the present disclosure.

Referring to FIG. 5, the memory system 1000 according to an embodiment of the present disclosure may include a memory device 1200 and a controller 1100.

The memory device 1200 may be used to store data information having various data formats such as texts, graphics, and software codes. The memory device 1200 may be a nonvolatile memory, and may include the structures described with reference to FIGS. 1A to 4. In addition, the memory device 1200 may include a source layer, a stack structure, a channel layer, a slit, and a source pick-up line. The source layer may include at least one groove in an upper surface thereof. The stack structure may be formed over the source layer. The channel layer may pass through the stack structure. The channel layer may be in contact with the source layer. The slit may pass through the stack structure. The slit may expose the groove of the source layer therethrough. The source pick-up line may be formed in the slit and the groove. The source pick-up line may be in contact with the source layer. The structure and manufacturing method of the memory device 1200 are the same as described above, and therefore any repetitive detailed descriptions thereof will be omitted.

The controller 1100 may be electrically connected to a host and the memory device 1200, and may access the memory device 1200 in response to a request from the host. For example, the controller 1100 may control reading, writing, erasing, and background operations of the memory device 1200.

The controller 1100 may include a random access memory (RAM) 1110, a central processing unit (CPU) 1120, a host interface 1130, an error correction code (ECC) circuit 1140, a memory interface 1150, and the like.

Here, the RAM 1110 may be used as an operation memory of the CPU 1120, a cache memory between the memory device 1200 and the host, and a buffer memory between the memory device 1200 and the host. For reference, the RAM 1110 may be replaced with a static random access memory (SRAM), a read only memory (ROM), etc.

The CPU 1120 may control overall operations of the controller 1100. For example, the CPU 1120 may operate firmware such as a flash translation layer (FTL) stored in the RAM 1110.

The host interface 1130 may interface with the host. For example, the controller 1100 may communicate with the host using at least one of a variety of interface protocols, such as a universal serial bus (USB) protocol, a multimedia card (MMC) protocol, a peripheral component interconnection (PCI) protocol, a PCI-Express (PCI-E) protocol, an advanced technology attachment (ATA) protocol, a Serial-ATA protocol, a Parallel-ATA protocol, a small computer small interface (SCSI) protocol, an enhanced small disk interface (ESDI) protocol, an integrated drive electronics (IDE) protocol, and a private protocol.

The ECC circuit 1140 may detect and correct an error included in data that is read from the memory device 1200, using an error correction code (ECC).

The memory interface 1150 may interface with the memory device 1200. For example, the memory interface 1150 may include an NAND interface or NOR interface.

For reference, the controller 1100 may further include a buffer memory (not illustrated) for temporarily storing data. Here, the buffer memory may be used to temporarily store data transferred to an external device through the host interface 1130 or data transferred from the memory device 1200 through the memory interface 1150. The controller 1100 may further include a ROM that stores code data for interfacing with the host.

As described above, the memory system 1000 according to an embodiment of the present disclosure may include the memory device 1200 having a stable structure and improved characteristics, and thus it is possible to improve characteristics of the memory system 1000.

FIG. 6 is a block diagram illustrating an example configuration of a memory system according to an embodiment of the present disclosure. Hereinafter, any repetitive detailed description will be omitted or simplified.

In FIG. 6, the memory system 1000′ according to an embodiment of the present disclosure may include a memory device 1200′ and a controller 1100. The controller 1100 may include a RAM 1110, a CPU 1120, a host interface 1130, an ECC circuit 1140, a memory interface 1150, and the like.

The memory device 1200′ may be a nonvolatile memory, and may include the structures described with reference to FIGS. 1A to 4. In addition, the memory device 1200′ may include a source layer, a stack structure, a channel layer, a slit, and a source pick-up line. The source layer may include at least one groove in an upper surface thereof. The stack structure may be formed over the source layer. The channel layer may pass through the stack structure. The channel layer may be in contact with the source layer. The slit may pass through the stack structure. The slit may expose the groove of the source layer therethrough. The source pick-up line may be formed in the slit and the groove. The source pick-up line may be in contact with the source layer. The structure and manufacturing method of the memory device 1200′ are the same as described above, and therefore any repetitive detailed descriptions thereof will be omitted.

The memory device 1200′ may be a multi-chip package including a plurality of memory chips. The plurality of memory chips may be divided into a plurality of groups, which are configured to communicate with the controller 1100 over first to kth channels (CH1 to CHk). In addition, memory chips included in one group may be configured to communicate with the controller 1100 over a common channel. For reference, the memory system 1000′ may be modified such that one memory chip is connected to one channel.

As described above, the memory system 1000′ according to an embodiment of the present disclosure may include the memory device 1200′ having a stable structure and improved characteristics, and thus it is possible to improve characteristics of the memory system 1000′. Particularly, the memory device 1200′ is configured as a multi-chip package, so that it is possible to increase the data storage capacity of the memory system 1000′ and to improve the operation speed of the memory system 1000′.

FIG. 7 is a diagram illustrating an example configuration of a computing system according to an embodiment of the present disclosure. Hereinafter, any repetitive detailed description will be omitted or simplified.

In FIG. 7, the computing system 2000 according to an embodiment of the present disclosure may include a memory device 2100, a CPU 2200, a RAM 2300, a user interface 2400, a power source 2500, a system bus 2600, and the like.

The memory device 2100 may store data provided through the user interface 2400, data processed by the CPU 2200, and the like. In addition, the memory device 2100 may be electrically connected to the CPU 2200, the RAM 2300, the user interface 2400, the power source 2500, and the like through the system bus 2600. For example, the memory device 2100 may be electrically connected to the system bus 2600 through a controller (not illustrated) or directly. When the memory device 2100 is directly connected to the system bus 2600, a function of the controller may be performed by the CPU 2200, the RAM 2300, etc.

Here, the memory device 2100 may be a nonvolatile memory, and may include the structures described with reference to FIGS. 1A to 4. In addition, the memory device 2100 may include a source layer, a stack structure, a channel layer, a slit, and a source pick-up line. The source layer may include at least one groove in an upper surface thereof. The stack structure may be formed over the source layer. The channel layer may pass through the stack structure. The channel layer may be in contact with the source layer. The slit may pass through the stack structure. The slit may expose the groove of the source layer therethrough. The source pick-up line may be formed in the slit and the groove. The source pick-up line may be in contact with the source layer. The structure and manufacturing method of the memory device 2100 are the same as described above, and therefore any repetitive detailed descriptions thereof will be omitted.

The memory device 2100 may be a multi-chip package including a plurality of memory chips as described with reference to FIG. 6.

The computing system 2000 configured as described above may be a computer, a ultra mobile PC (UMPC), a workstation, a netbook, a personal digital assistant (PDA), a portable computer, a web tablet, a wireless phone, a mobile phone, a smartphone, an e-book, a portable multimedia player (PMP), a portable game console, a navigation device, a black box, a digital camera, a 3-dimensional television, a digital audio recorder, a digital audio player, a digital picture recorder, a digital picture player, a digital video recorder, a digital video player, a device for communicating information in a wireless environment, one of a variety of electronic devices constituting a home network, one of a variety of electronic devices constituting a computer network, one of a variety of electronic devices constituting a telematics network, an RFID device, etc.

As described above, the computing system 2000 according to an embodiment of the present disclosure may include the memory device 2100 having a stable structure and improved characteristics, and thus it is possible to improve characteristics of the computing system 2000.

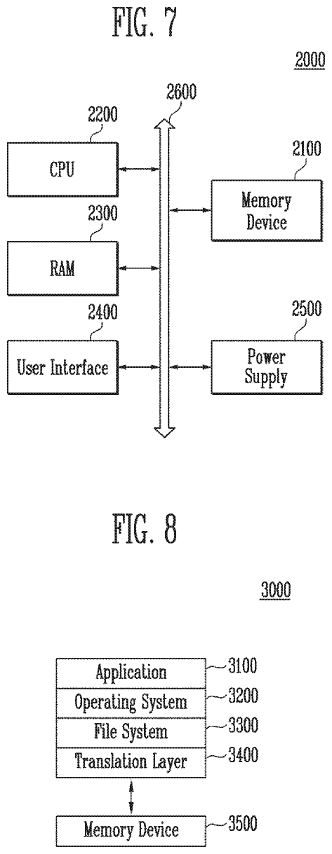

FIG. 8 is a diagram illustrating an example of a computing system according to an embodiment of the present disclosure.

In FIG. 8, the computing system 3000 according to an embodiment of the present disclosure may include a software layer including an operating system 3200, an application 3100, a file system 3300, a translation layer 3400, and the like. In addition, the computing system 3000 may include a hardware layer of a memory device 3500, etc.

The operating system 3200 may manage software resources, hardware resources, etc. of the computing system 3000, and control program execution of a central processing unit. The application 3100 may be one of a variety of application programs running on the computing system 3000, and may be a utility executed by the operating system 3200.

The file system 3300 may mean a logical structure for managing data, files, etc. in the computing system 3000, and may organize the data or files stored in the memory device 3500 according to a rule. The file system 3300 may be determined depending on the operating system 3200 used in the computing system 3000. For example, when the operating system 3200 is one of Windows operating systems of Microsoft, the file system 3300 may be a file allocation table (FAT) or a NT file system (NTFS). When the operating system 3200 is one of Unix/Linux operating systems, the file system 3300 may be an extended file system (EXT), a Unix file system (UFS), or a journaling file system (JFS).

Although the operating system 3200, the application 3100, and the file system 3300 are illustrated as being individual blocks, the application 3100 and the file system 3300 may be included in the operating system 3200.

The translation layer 3400 may translate an address into a form suitable for the memory device 3500 in response to a request from the file system 3300. For example, the translation layer 3400 may translate a logical address generated by the file system 3300 into a physical address of the memory device 3500. Here, mapping information between the logical address and the physical address may be stored as an address translation table. For example, the translation layer 3400 may be a flash translation layer (FTL), a universal flash storage link layer (ULL), etc.

The memory device 3500 may be a nonvolatile memory, and may include the structures described with reference to FIGS. 1A to 4. In addition, the memory device 3500 may include a source layer, a stack structure, a channel layer, a slit, and a source pick-up line. The source layer may include at least one groove in an upper surface thereof. The stack structure may be formed over the source layer. The channel layer may pass through the stack structure. The channel layer may be in contact with the source layer. The slit may pass through the stack structure. The slit may expose the groove of the source layer therethrough. The source pick-up line may be formed in the slit and the groove. The source pick-up line may be in contact with the source layer. The structure and manufacturing method of the memory device 3500 are the same as described above, and therefore any repetitive detailed descriptions thereof will be omitted.

The computing system 3000 configured as described above may be divided into an operating system layer performed in an upper level region and a controller layer performed in a lower level region. Here, the application 3100, the operating system 3200, and the file system 3300 may be included in the operating system layer, and may be driven by the operation memory of the computing system 3000. In addition, the translation layer 3400 may be included in the operating system layer or the controller layer.

As described above, the computing system 3000 according to an embodiment of the present disclosure may include the memory device 3500 having a stable structure and improved characteristics, and thus it is possible to improve characteristics of the computing system 3000.

According to various embodiments of the present disclosure, it is possible to reduce difficulties in a manufacturing process of a semiconductor device and to improve characteristics of the semiconductor device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

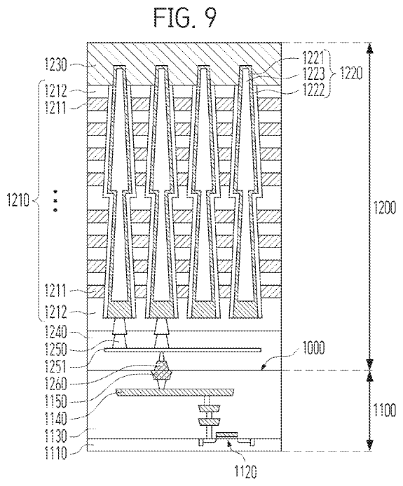

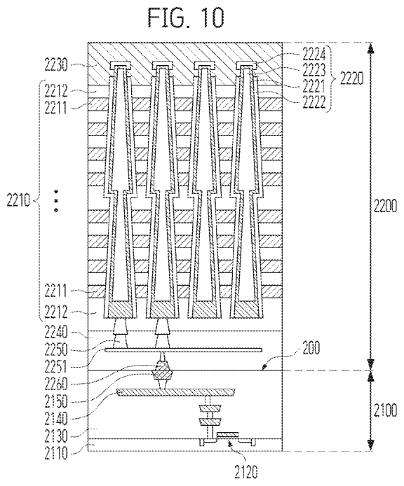

FIG. 9 is a diagram illustrating the structure of a semiconductor device in accordance with an embodiment.

Referring to FIG. 9, the semiconductor device may include a first semiconductor structure 1100 and a second semiconductor structure 1200. A bonding interface 1000 may be located in the semiconductor device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit, and the second semiconductor structure 1200 may include a memory cell array.

The first semiconductor structure 1100 may include a substrate 1110, a transistor 1120, a first interlayer insulating layer 1130, a first interconnection structure 1140, and a first bonding pad 1150. The transistor 1120 may be included in the peripheral circuit. The peripheral circuit may include a row decoder, a page buffer, an input/output circuit, a logic circuit, and the like. The first interconnection structure 1140 may be disposed in the first interlayer insulating layer 1130 and may include a via, a wiring line, and the like. The first bonding pad 1150 may be disposed at the bonding interface 1000 and may be electrically connected to the peripheral circuit through the first interconnection structure 1140.

The second semiconductor structure 1200 may include a gate structure 1210, a channel structure 1220, a source structure 1230, a second interlayer insulating layer 1240, a second interconnection structure 1250, and a second bonding pad 1260. The gate structure 1210 may include gate lines 1211 alternately stacked with insulating layers 1212. The source structure 1230 may be disposed over the gate structure 1210. The channel structure 1220 may include a channel layer 1221, a memory layer 1222, and/or an insulating core 1223. The channel layer 1221 may extend through the gate structure 1210 and may be connected to the source structure 1230. The second interconnection structure 1250 may be disposed in the second interlayer insulating layer 1240 and may include a via, a wiring line, and the like. For example, the second interconnection structure 1250 may include a bitline 1251. The second bonding pad 1260 may be disposed at the bonding interface 1000 and may be electrically connected to the memory cell array through the second interconnection structure 1250.

The first bonding pad 1150 may be electrically connected to the second bonding pad 1260 at the bonding interface 1000, and the memory cell array may be electrically connected to the peripheral circuit through the first bonding pad 1150 and the second bonding pad 1260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate structure 1210, and the channel structure 1220 may be formed, flipped, and bonded to the first wafer including the transistor 1120. Subsequently, a rear surface of the gate structure 1210 may be exposed by removing the substrate of the second wafer, and the channel layer 1221 may be exposed by etching the memory layer 1222 of the channel structure 1220 protruding from the rear surface of the gate structure 1210. The source structure 1230 may be formed on the rear surface of the gate structure 1210.

FIG. 10 is a diagram illustrating the structure of a semiconductor device in accordance with an embodiment.

Referring to FIG. 10, the semiconductor device may include a first semiconductor structure 2100 and a second semiconductor structure 2200. A bonding interface 2000 may be located in the semiconductor device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit, and the second semiconductor structure 2200 may include a memory cell array.

The first semiconductor structure 2100 may include a substrate 2110, a transistor 2120, a first interlayer insulating layer 2130, a first interconnection structure 2140, and a first bonding pad 2150. The transistor 2120 may be included in the peripheral circuit. The peripheral circuit may include a row decoder, a page buffer, an input/output circuit, a logic circuit, and the like. The first interconnection structure 2140 may be disposed in the first interlayer insulating layer 2130 and may include a via, a wiring line, and the like. The first bonding pad 2150 may be disposed at the bonding interface 2000 and may be electrically connected to the peripheral circuit through the first interconnection structure 2140.

The second semiconductor structure 2200 may include a gate structure 2210, a channel structure 2220, a source structure 2230, a second interlayer insulating layer 2240, a second interconnection structure 2250, and a second bonding pad 2260. The gate structure 2210 may include gate lines 2211 alternately stacked with insulating layers 2212. The source structure 2230 may be disposed over the gate structure 2210. The channel structure 2220 may include a channel layer 2221, a memory layer 2222, an insulating core 2223, and/or a memory pattern 2224. The channel layer 2221 may extend through the gate structure 2210 and may be connected to the source structure 2230. The second interconnection structure 2250 may be disposed in the second interlayer insulating layer 2240 and may include a via, a wiring line, and the like. For example, the second interconnection structure 2250 may include a bitline 2251. The second bonding pad 2260 may be disposed at the bonding interface 2000 and may be electrically connected to the memory cell array through the second interconnection structure 2250.

The first bonding pad 2150 may be electrically connected to the second bonding pad 2260 at the bonding interface 2000, and the memory cell array may be electrically connected to the peripheral circuit through the first bonding pad 2150 and the second bonding pad 2260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 2230 may be connected to the channel layer 2221 using a source sacrificial layer. For example, the channel structure 2220 may be formed to protrude into a source structure including the source sacrificial layer. An opening exposing the channel structure 2220 may be formed by removing the source sacrificial layer, and the channel layer 2221 may be exposed by etching the memory layer 2222 through the opening. A source layer connected to the channel layer 2221 may be formed in the opening to form the source structure 2230 including the source layer. The second wafer including the source structure 2230 may be flipped and bonded to the first wafer including the transistor 2120.

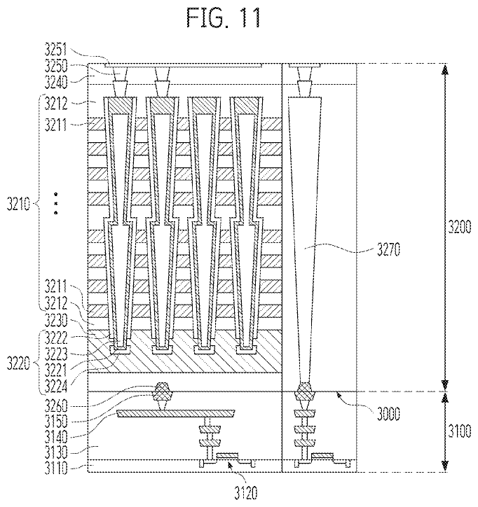

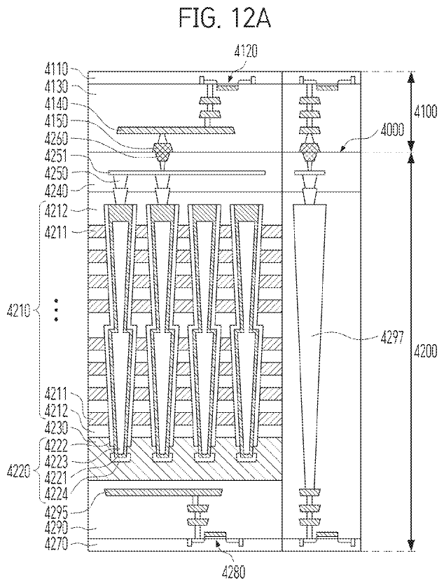

FIG. 11 is a diagram illustrating the structure of a semiconductor device in accordance with an embodiment.

Referring to FIG. 11, the semiconductor device may include a first semiconductor structure 3100 and a second semiconductor structure 3200. A bonding interface 3000 may be located in the semiconductor device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit, and the second semiconductor structure 3200 may include a memory cell array.

The first semiconductor structure 3100 may include a substrate 3110, a transistor 3120, a first interlayer insulating layer 3130, a first interconnection structure 3140, and a first bonding pad 3150. The transistor 3120 may be included in the peripheral circuit. The peripheral circuit may include a row decoder, a page buffer, an input/output circuit, a logic circuit, and the like. The first interconnection structure 3140 may be disposed in the first interlayer insulating layer 3130 and may include a via, a wiring line, and the like. The first bonding pad 3150 may be disposed at the bonding interface 3000 and may be electrically connected to the peripheral circuit through the first interconnection structure 3140.

The second semiconductor structure 3200 may include a gate structure 3210, a channel structure 3220, a source structure 3230, a second interlayer insulating layer 3240, a second interconnection structure 3250, a second bonding pad 3260, and a contact plug 3270. The gate structure 3210 may include gate lines 3211 alternately stacked with insulating layers 3212. The source structure 3230 may be disposed below the gate structure 3210. The channel structure 3220 may include a channel layer 3221, a memory layer 3222, an insulating core 3223, and/or a memory pattern 3224. The channel layer 3221 may extend through the gate structure 3210, and may be connected to the source structure 3230. The second interconnection structure 3250 may be disposed in the second interlayer insulating layer 3240 and may include a via, a wiring line, and the like. For example, the second interconnection structure 3250 may include a bitline 3251. The second bonding pad 3260 may be disposed at the bonding interface 3000 and may be electrically connected to the memory cell array through the second interconnection structure 3250.

The first bonding pad 3150 may be electrically connected to the second bonding pad 3260 at the bonding interface 3000, and the memory cell array may be electrically connected to the peripheral circuit through the first bonding pad 3150 and the second bonding pad 3260. The contact plug 3270 may extend through the second interlayer insulating layer 3240 or a dummy stack and may be connected to the peripheral circuit through the first bonding pad 3150 and the second bonding pad 3260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 3230 may be connected to the channel layer 3221 using a source sacrificial layer. For example, the channel structure 3220 protrudes into a source structure including the source sacrificial layer. Subsequently, an opening exposing the channel structure 3220 may be formed by removing the source sacrificial layer, and the channel layer 3221 may be exposed by etching the memory layer 3222 through the opening. A source layer connected to the channel layer 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

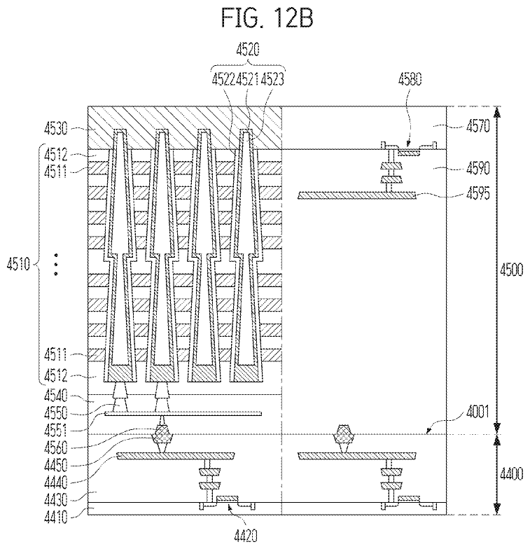

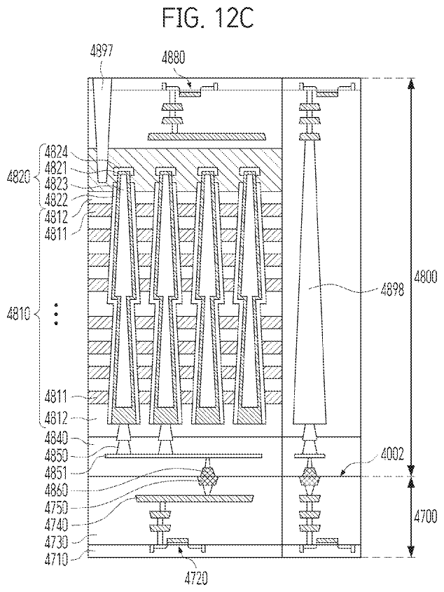

FIG. 12A is a diagram illustrating the structure of a semiconductor device in accordance with an embodiment.

Referring to FIG. 12A, the semiconductor device may include a first semiconductor structure 4100 and a second semiconductor structure 4200. A bonding interface 4000 may be located in the semiconductor device, and the first semiconductor structure 4100 may be distinguished from the second semiconductor structure 4200 by the bonding interface 4000. The second semiconductor structure 4200 may be disposed over or under the first semiconductor structure 4100. A peripheral circuit may include a first peripheral circuit and a second peripheral circuit. The first peripheral circuit and the second peripheral circuit may be distributed and disposed in the first semiconductor structure 4100 and the second semiconductor structure 4200. The first semiconductor structure 4100 may include the first peripheral circuit, and the second semiconductor structure 4200 may include the second peripheral circuit and a memory cell array.

The first semiconductor structure 4100 may include a first substrate 4110, a first transistor 4120, a first interlayer insulating layer 4130, a first interconnection structure 4140, and a first bonding pad 4150. The first transistor 4120 may be included in the first peripheral circuit. The first peripheral circuit may include a row decoder, a page buffer, an input/output circuit, a logic circuit, and the like. The first interconnection structure 4140 may be disposed in the first interlayer insulating layer 4130 and may include a via, a wiring line, and the like. The first bonding pad 4150 may be disposed at the bonding interface 4000 and may be electrically connected to the first peripheral circuit through the first interconnection structure 4140.

The second semiconductor structure 4200 may include a gate structure 4210, a channel structure 4220, a source structure 4230, a second interlayer insulating layer 4240, a second interconnection structure 4250, a second bonding pad 4260, a second substrate 4270, a second transistor 4280, a third interlayer insulating layer 4290, a third interconnection structure 4295, and a contact plug 4297.

The second transistor 4280 may be disposed on the second substrate 4270. The second transistor 4280 may be included in the second peripheral circuit. The second peripheral circuit may include a row decoder, a page buffer, an input/output circuit, a logic circuit, and the like. The third interconnection structure 4295 may be formed in the third interlayer insulating layer 4290 and may include a via, a wiring line, and the like. The third interconnection structure 4295 may be electrically connected to the second peripheral circuit.

The gate structure 4210 may be disposed over the second peripheral circuit. The gate structure 4210 may include gate lines 4211 alternately stacked with insulating layers 4212. The source structure 4230 may be disposed under the gate structure 4210. The channel structure 4220 may include a channel layer 4221, a memory layer 4222, an insulating core 4223, and/or a memory pattern 4224. The channel layer 4221 may extend through the gate structure 4210 and may be connected to the source structure 4230. The second interconnection structure 4250 may be disposed in the second interlayer insulating layer 4240 and may include a via, a wiring line, and the like. For example, the second interconnection structure 4250 may include a bitline 4251. The second bonding pad 4260 may be disposed at the bonding interface 4000 and may be electrically connected to the memory cell array through the second interconnection structure 4250.

The first bonding pad 4150 may be electrically connected to the second bonding pad 4260 at the bonding interface 4000, and the memory cell array may be electrically connected to the first peripheral circuit through the first bonding pad 4150 and the second bonding pad 4260. The contact plug 4297 may extend through the second interlayer insulating layer 4240 or a dummy stack. The first peripheral circuit may be connected to the second peripheral circuit through the contact plug 4297, the first bonding pad 4150 and the second bonding pad 4260.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

When the second wafer is manufactured, the source structure 4230 may be connected to the channel layer 4221 using a source sacrificial layer. For example, the second peripheral circuit may be formed on the second substrate 4270, and a source structure including the source sacrificial layer and the channel structure 4220 protruding into the source structure may be formed over the second peripheral circuit. An opening exposing the channel structure 4220 may be formed by removing the source sacrificial layer, and the channel layer 4221 may be exposed by etching the memory layer 4222 through the opening. A source layer connected to the channel layer 4221 may be formed in the opening to form the source structure 4230 including the source layer. The second wafer including the second peripheral circuit and the source structure 4230 may be bonded to the first wafer including the first peripheral circuit.

FIG. 12B is a diagram illustrating the structure of a semiconductor device in accordance with an embodiment.

Referring to FIG. 12B, the semiconductor device may include a first semiconductor structure 4400 and a second semiconductor structure 4500. A bonding interface 4001 may be located in the semiconductor device, and the first semiconductor structure 4400 may be distinguished from the second semiconductor structure 4500 by the bonding interface 4001. The second semiconductor structure 4500 may be disposed over or under the first semiconductor structure 4400. A peripheral circuit may include a first peripheral circuit and a second peripheral circuit. The first peripheral circuit and the second peripheral circuit may be distributed and disposed in the first semiconductor structure 4400 and the second semiconductor structure 4500. The first semiconductor structure 4400 may include the first peripheral circuit, and the second semiconductor structure 4500 may include the second peripheral circuit and a memory cell array.

The first semiconductor structure 4400 may include a first substrate 4410, a first transistor 4420, a first interlayer insulating layer 4430, a first interconnection structure 4440, and a first bonding pad 4450. The first transistor 4420 may be included in the first peripheral circuit. The first peripheral circuit may include a row decoder, a page buffer, an input/output circuit, a logic circuit, and the like. The first interconnection structure 4440 may be disposed in the first interlayer insulating layer 4430 and may include a via, a wiring line, and the like. The first interconnection structure 4440 may be electrically connected to the first peripheral circuit.

The second semiconductor structure 4500 may include a gate structure 4510, a channel structure 4520, a source structure 4530, a second interlayer insulating layer 4540, a second interconnection structure 4550, a second bonding pad 4560, a second substrate 4570, a second transistor 4580, a third interlayer insulating layer 4590, and a third interconnection structure 4595.

The second transistor 4580 may be disposed on the second substrate 4570. The second transistor 4580 may be included in the second peripheral circuit. The third interconnection structure 4595 may be formed in the third interlayer insulating layer 4590 and may include a via, a wiring line, and the like. The third interconnection structure 4595 may be electrically connected to the second peripheral circuit.

The source structure 4530 may be disposed at a level corresponding to the second substrate 4570, and the gate structure 4510 may be disposed under the source structure 4530. The gate structure 4510 may include gate lines 4511 alternately stacked with insulating layers 4512. The channel structure 4520 may include a channel layer 4521, a memory layer 4522, and/or an insulating core 4523. The channel layer 4521 may extend through the gate structure 4510 and may be connected to the source structure 4530. The second interconnection structure 4550 may be disposed in the second interlayer insulating layer 4540 and may include a via, a wiring line, and the like. For example, the second interconnection structure 4550 may include a bitline 4551. The second bonding pad 4560 may be disposed at the bonding interface 4001, and may be electrically connected to the memory cell array through the second interconnection structure 4550.

The first bonding pad 4450 may be electrically connected to the second bonding pad 4560 at the bonding interface 4001, and the memory cell array may be electrically connected to the first peripheral circuit through the first bonding pad 4450 and the second bonding pad 4560.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4400 and the second semiconductor structure 4500 may be formed after the first wafer is bonded to the second wafer. For example, the second peripheral circuit may be formed in a peripheral region of the second substrate 4560, and the channel structure 4520 protruding into the second substrate 4570 may be formed in a cell region of the second substrate 4570. The second wafer including the second peripheral circuit and the source structure 4530 may be flipped and bonded to the first wafer including the first peripheral circuit. Subsequently, a rear surface of the gate structure 4510 may be exposed by removing the cell region of the second substrate 4570, and the channel layer 4521 may be exposed by etching the memory layer 4522 of the channel structure 4520 protruding from the rear surface of the gate structure 4510. The source structure 4530 may be formed on the rear surface of the gate structure 4510.

FIG. 12C is a diagram illustrating the structure of a semiconductor device in accordance with an embodiment.

Referring to FIG. 12C, the semiconductor device may include a first semiconductor structure 4700 and a second semiconductor structure 4800. A bonding interface 4002 may be located in the semiconductor device, and the first semiconductor structure 4700 may be distinguished from the second semiconductor structure 4800 by the bonding interface 4002. The second semiconductor structure 4800 may be disposed over or under the first semiconductor structure 4700. A peripheral circuit may include a first peripheral circuit and a second peripheral circuit. The first peripheral circuit and the second peripheral circuit may be distributed and disposed in the first semiconductor structure 4700 and the second semiconductor structure 4800. The first semiconductor structure 4700 may include the first peripheral circuit, and the second semiconductor structure 4800 may include the second peripheral circuit and a memory cell array.

The first semiconductor structure 4700 may include a first substrate 4710, a first transistor 4720, a first interlayer insulating layer 4730, a first interconnection structure 4740, and a first bonding pad 4750. The first transistor 4720 may be included in the first peripheral circuit. The first peripheral circuit may include a row decoder, a page buffer, an input/output circuit, a logic circuit, and the like. The first interconnection structure 4740 may be disposed in the first interlayer insulating layer 4730 and may include a via, a wiring line, and the like. The first bonding pad 4750 may be disposed at the bonding interface 4002 and may be electrically connected to the first peripheral circuit through the first interconnection structure 4740.

The second semiconductor structure 4800 may include a gate structure 4810, a channel structure 4820, a source structure 4830, a second interlayer insulating layer 4840, a second interconnection structure 4850, a second bonding pad 4860, a second substrate 4870, a second transistor 4880, a third interlayer insulating layer 4890, a third interconnection structure 4895, a through via 4897, and a contact plug 4898.

The second transistor 4880 may be disposed on the second substrate 4870. The second transistor 4880 may be included in the second peripheral circuit. The second peripheral circuit may include a row decoder, a page buffer, an input/output circuit, a logic circuit, and the like. The third interconnection structure 4895 may be formed in the third interlayer insulating layer 4890 and may include a via, a wiring line, and the like. The third interconnection structure 4895 may be electrically connected to the second peripheral circuit.

The source structure 4830 may be disposed under the second peripheral circuit. The through via 4897 may extend through the second substrate 4870 and the third interlayer insulating layer 4890 and may be connected to the source structure 4830. The gate structure 4810 may be disposed under the source structure 4830. The gate structure 4810 may include gate lines 4811 alternately stacked with insulating layers 4812. The channel structure 4820 may include a channel layer 4821, a memory layer 4822, an insulating core 4823, and/or a memory pattern 4824. The channel layer 4821 may extend through the gate structure 4810 and may be connected to the source structure 4830. The second interconnection structure 4850 may be disposed in the second interlayer insulating layer 4840 and may include a via, a wiring line, and the like. For example, the second interconnection structure 4850 may include a bitline 4851. The second bonding pad 4860 may be disposed at the bonding interface 4002 and may be electrically connected to the memory cell array through the second interconnection structure 4850.

The first bonding pad 4750 may be electrically connected to the second bonding pad 4860 at the bonding interface 4002, and the memory cell array may be electrically connected to the first peripheral circuit through the first bonding pad 4750 and the second bonding pad 4860. The contact plug 4898 may extend through the second interlayer insulating layer 4840 or a dummy stack. The first peripheral circuit may be connected to the second peripheral circuit through the contact plug 4898, the first bonding pad 4750 and the second bonding pad 4860.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit, and a source structure including a source sacrificial layer may be formed. The second wafer may be flipped and bonded to the first wafer including the first peripheral circuit. Subsequently, a through hole extending through the second substrate 4870 and the third interlayer insulating layer 4890 to expose the source sacrificial layer may be formed, and an opening, through which the channel structure 4820 is exposed, may be formed by removing the source sacrificial layer through the through hole. The channel layer 4821 may be exposed by etching the memory layer 4822 through the opening, and a source layer connected to the channel layer 4821 may be formed in the opening to form the source structure 4830 including the source layer. The through via 4897 may be formed in the through hole.

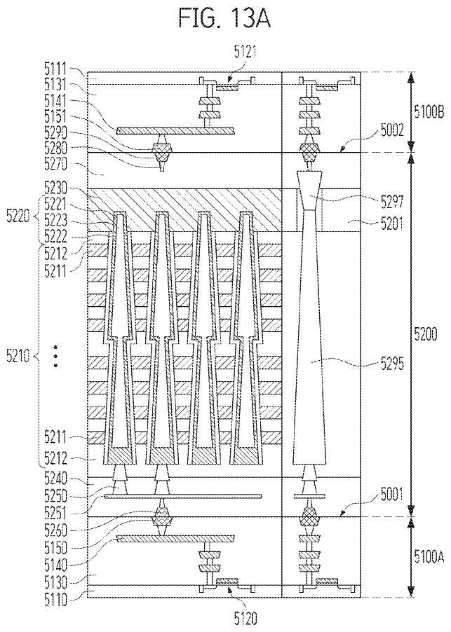

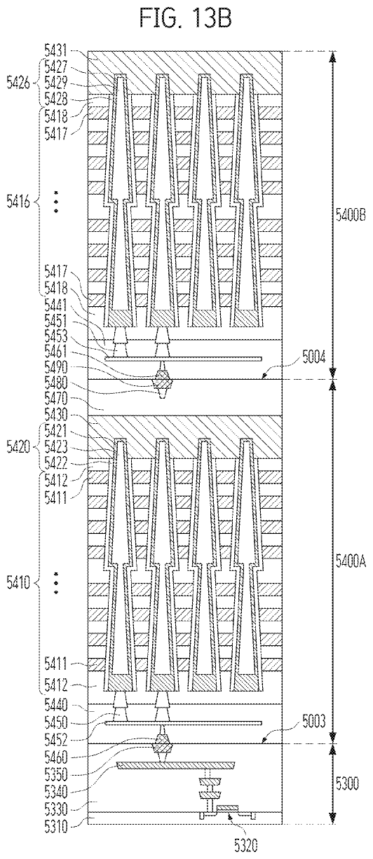

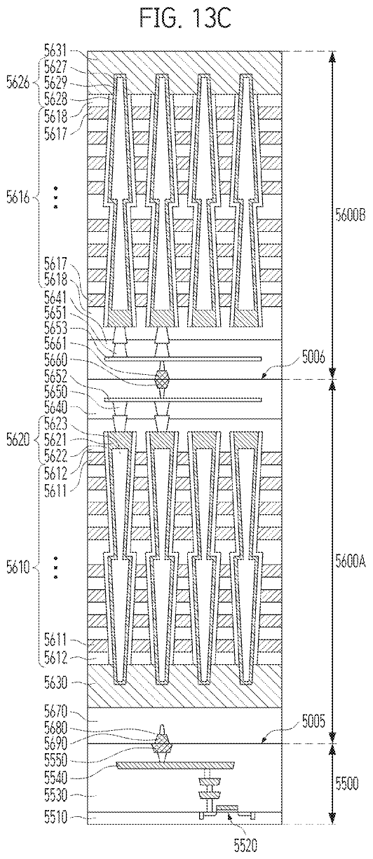

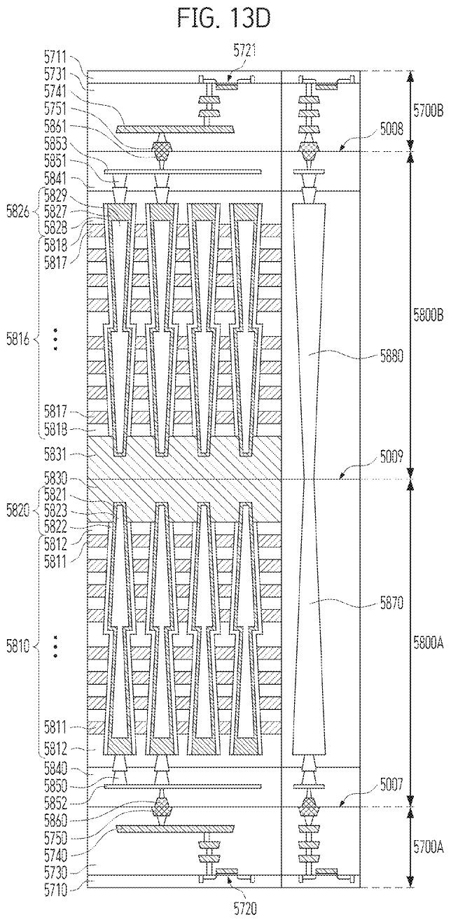

FIG. 13A is a diagram illustrating the structure of a semiconductor device in accordance with an embodiment.

Referring to FIG. 13A, the semiconductor device may include a first semiconductor structure 5100A, a second semiconductor structure 5100B, and a third semiconductor structure 5200. Bonding interfaces 5001 and 5002 may be located in the semiconductor device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit may include a first peripheral circuit and a second peripheral circuit. The first peripheral circuit and the second peripheral circuit may be distributed and disposed in the first semiconductor structure 5100A and the second semiconductor structure 5100B. The first semiconductor structure 5100A may include the first peripheral circuit, the second semiconductor structure 5100B may include the second peripheral circuit, and the third semiconductor structure 5200 may include a memory cell array.

The first semiconductor structure 5100A may include a first substrate 5110, a first transistor 5120, a first interlayer insulating layer 5130, a first interconnection structure 5140, and a first bonding pad 5150. The first transistor 5120 may be included in the first peripheral circuit. The first peripheral circuit may include a row decoder, a page buffer, an input/output circuit, a logic circuit, and the like. The first interconnection structure 5140 may be disposed in the first interlayer insulating layer 5130 and may include a via, a wiring line, and the like. The first bonding pad 5150 may be disposed at a first bonding interface 5001 and may be electrically connected to the first peripheral circuit through the first interconnection structure 5140.

The second semiconductor structure 5100B may include a second substrate 5111, a second transistor 5121, a second interlayer insulating layer 5131, a second interconnection structure 5141, and a second bonding pad 5151. The second transistor 5121 may be included in the second peripheral circuit. The second peripheral circuit may include a row decoder, a page buffer, an input/output circuit, a logic circuit, and the like. The second interconnection structure 5141 may be disposed in the second interlayer insulating layer 5131 and may include a via, a wiring line, and the like. The second bonding pad 5151 may be disposed at a second bonding interface 5002 and may be electrically connected to the second peripheral circuit through the second interconnection structure 5141.

The third semiconductor structure 5200 may include a substrate 5201, a gate structure 5210, a channel structure 5220, a source structure 5230, a third interlayer insulating layer 5240, a third interconnection structure 5250, a third bonding pad 5260, a fourth interlayer insulating layer 5270, a fourth interconnection structure 5280, a fourth bonding pad 5290, a first contact plug 5295, and a second contact plug 5297. The gate structure 5210 may include gate lines 5211 alternately stacked with insulating layers 5212. The source structure 5230 may be disposed over or under the gate structure 5210. The channel structure 5220 may include a channel layer 5221, a memory layer 5222, and/or an insulating core 5223. The channel layer 5221 may extend through the gate structure 5210 and may be connected to the source structure 5230. The third interconnection structure 5250 may be disposed in the third interlayer insulating layer 5240 and may include a via, a wiring line, and the like. For example, the third interconnection structure 5250 may include a bitline 5251. The fourth interconnection structure 5280 may be disposed in the fourth interlayer insulating layer 5270 and may include a via, a wiring line, and the like. The third bonding pad 5260 may be disposed at the first bonding interface 5001 and may be electrically connected to the memory cell array through the third interconnection structure 5250. The fourth bonding pad 5290 may be disposed at the second bonding interface 5002 and may be electrically connected to the memory cell array through the fourth interconnection structure 5280.

The first bonding pad 5150 may be electrically connected to the third bonding pad 5260 at the first bonding interface 5001, and the memory cell array may be electrically connected to the first peripheral circuit through the first bonding pad 5150 and the third bonding pad 5260. The second bonding pad 5151 may be electrically connected to the fourth bonding pad 5290 at the second bonding interface 5002, and the memory cell array may be electrically connected to the second peripheral circuit through the second bonding pad 5151 and the fourth bonding pad 5290.

The first contact plug 5295 may extend through the second interlayer insulating layer 5240 or a dummy stack, and the second contact plug 5297 may extend through the third substrate 5201. The first contact plug 5295 may be connected to the second contact plug 5297, and the first peripheral circuit may be connected to the second peripheral circuit through the first bonding pad 5150, the third bonding pad 5260, the first contact plug 5295, the second contact plug 5297, the fourth bonding pad 5290, and the second bonding pad 5151.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the second peripheral circuit, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 13B is a diagram illustrating the structure of a semiconductor device in accordance with an embodiment.

Referring to FIG. 13B, the semiconductor device may include a first semiconductor structure 5300, a second semiconductor structure 5400A, and a third semiconductor structure 5400B. Bonding interfaces 5003 and 5004 may be located in the semiconductor device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit, the second semiconductor structure 5400A may include a first memory cell array, and the third semiconductor structure 5400B may include a second memory cell array.

The first semiconductor structure 5300 may include a substrate 5310, a transistor 5320, a first interlayer insulating layer 5330, a first interconnection structure 5340, and a first bonding pad 5350. The transistor 5320 may be included in the peripheral circuit. The peripheral circuit may include a row decoder, a page buffer, an input/output circuit, a logic circuit, and the like. The first interconnection structure 5340 may be disposed in the first interlayer insulating layer 5330 and may include a via, a wiring line, and the like. The first bonding pad 5350 may be disposed at a first bonding interface 5003 and may be electrically connected to the peripheral circuit through the first interconnection structure 5340.

The second semiconductor structure 5400A may include a first gate structure 5410, a first channel structure 5420, a first source structure 5430, a second interlayer insulating layer 5440, a second interconnection structure 5450, a second bonding pad 5460, a third interlayer insulating layer 5470, a third interconnection structure 5480, and a third bonding pad 5490. The first gate structure 5410 may include first gate lines 5411 alternately stacked with first insulating layers 5412. The first source structure 5430 may be disposed over or under the first gate structure 5410. The first channel structure 5420 may include a first channel layer 5421, a first memory layer 5422, and/or a first insulating core 5423. The first channel layer 5421 may extend through the first gate structure 5410 and may be connected to the first source structure 5430. The second interconnection structure 5450 may be disposed in the second interlayer insulating layer 5440 and may include a via, a wiring line, and the like. For example, the second interconnection structure 5450 may include a bitline 5452. The third interconnection structure 5480 may be disposed in the third interlayer insulating layer 5470 and may include a via, a wiring line, and the like. The second bonding pad 5460 may be disposed at the first bonding interface 5003 and may be electrically connected to the first memory cell array through the second interconnection structure 5450. The third bonding pad 5490 may be disposed at a second bonding interface 5004, and may be electrically connected to the first memory cell array through the third interconnection structure 5480.

The third semiconductor structure 5400B may include a second gate structure 5416, a second channel structure 5426, a second source structure 5431, a fourth interlayer insulating layer 5441, a fourth interconnection structure 5451, and a fourth bonding pad 5461. The second gate structure 5416 may include second gate lines 5417 alternately stacked with second insulating layer 5418. The second source structure 5431 may be disposed over or under the second gate structure 5416. The second source structure 5431 may be electrically isolated from the first source structure 5430 and driven separately from the first source structure 5430 or may be electrically connected to the first source structure 5430 and driven in common with the first source structure 5430. The second channel structure 5426 may include a second channel layer 5427, a second memory layer 5428, and/or a second insulating core 5429. The second channel layer 5427 may extend through the second gate structure 5416 and may be connected to the second source structure 5431. The fourth interconnection structure 5451 may be disposed in the fourth interlayer insulating layer 5441 and may include a via, a wiring line, and the like. For example, the fourth interconnection structure 5451 may include a bitline 5453. The fourth bonding pad 5461 may be disposed at the second bonding interface 5004 and may be electrically connected to the second memory cell array through the fourth interconnection structure 5451.

The first bonding pad 5350 may be electrically connected to the second bonding pad 5460 at the first bonding interface 5003, and the first memory cell array may be electrically connected to the peripheral circuit through the first bonding pad 5350 and the second bonding pad 5460. The third bonding pad 5490 may be electrically connected to the fourth bonding pad 5461 at the second bonding interface 5004, and the second memory cell array may be electrically connected to the first memory cell array through the third bonding pad 5490 and the fourth bonding pad 5461.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 13C is a diagram illustrating the structure of a semiconductor device in accordance with an embodiment.

Referring to FIG. 13C, the semiconductor device may include a first semiconductor structure 5500, a second semiconductor structure 5600A, and a third semiconductor structure 5600B. Bonding interfaces 5005 and 5006 may be located in the semiconductor device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit, the second semiconductor structure 5600A may include a first memory cell array, and the third semiconductor structure 5600B may include a second memory cell array.

The first semiconductor structure 5500 may include a substrate 5510, a transistor 5520, a first interlayer insulating layer 5530, a first interconnection structure 5540, and a first bonding pad 5550. The transistor 5520 may be included in the peripheral circuit. The peripheral circuit may include a row decoder, a page buffer, an input/output circuit, a logic circuit, and the like. The first interconnection structure 5540 may be disposed in the first interlayer insulating layer 5530 and may include a via, a wiring line, and the like. The first bonding pad 5550 may be disposed at a first bonding interface 5005 and may be electrically connected to the peripheral circuit through the first interconnection structure 5540.

The second semiconductor structure 5600A may include a first gate structure 5610, a first channel structure 5620, a first source structure 5630, a second interlayer insulating layer 5640, a second interconnection structure 5650, a second bonding pad 5660, a third interlayer insulating layer 5670, a third interconnection structure 5680, and a third bonding pad 5690. The first gate structure 5610 may include first gate lines 5611 alternately stacked with first insulating layers 5612. The first source structure 5630 may be disposed over or under the first gate structure 5610. The first channel structure 5620 may include a first channel layer 5621, a first memory layer 5622, and/or a first insulating core 5623. The first channel layer 5621 may extend through the first gate structure 5610 and may be connected to the first source structure 5630. The second interconnection structure 5650 may be disposed in the second interlayer insulating layer 5640 and may include a via, a wiring line, and the like. For example, the second interconnection structure 5650 may include a bitline 5652. The third interconnection structure 5680 may be disposed in the third interlayer insulating layer 5670 and may include a via, a wiring line, and the like. The second bonding pad 5660 may be disposed at a second bonding interface 5006 and may be electrically connected to the first memory cell array through the second interconnection structure 5650. The third bonding pad 5690 may be disposed at the first bonding interface 5005 and may be electrically connected to the first memory cell array through the third interconnection structure 5680.

The third semiconductor structure 5600B may include a second gate structure 5616, a second channel structure 5626, a second source structure 5631, a fourth interlayer insulating layer 5641, a fourth interconnection structure 5651, and a fourth bonding pad 5661. The second gate structure 5616 may include second gate lines 5617 alternately stacked with second insulating layer 5618. The second source structure 5631 may be disposed over or under the second gate structure 5616. The second source structure 5631 may be electrically isolated from the first source structure 5630 and driven separately from the first source structure 5630 or may be electrically connected to the first source structure 5630 and driven in common with the first source structure 5630. The second channel structure 5626 may include a second channel layer 5627, a second memory layer 5628, and/or a second insulating core 5629. The second channel layer 5627 may extend through the second gate structure 5616 and may be connected to the second source structure 5631. The fourth interconnection structure 5651 may be disposed in the fourth interlayer insulating layer 5641 and may include a via, a wiring line, and the like. For example, the fourth interconnection structure 5651 may include a bitline 5653. The fourth bonding pad 5661 may be disposed at the second bonding interface 5006 and may be electrically connected to the second memory cell array through the fourth interconnection structure 5651.

The first bonding pad 5550 may be electrically connected to the third bonding pad 5690 at the first bonding interface 5005, and the first memory cell array may be electrically connected to the peripheral circuit through the first bonding pad 5550 and the third bonding pad 5690. The second bonding pad 5660 may be electrically connected to the fourth bonding pad 5661 at the second bonding interface 5006, and the second memory cell array may be electrically connected to the first memory cell array through the second bonding pad 5660 and the fourth bonding pad 5661.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 13D is a diagram illustrating the structure of a semiconductor device in accordance with an embodiment.

Referring to FIG. 13D, the semiconductor device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor device, and the first semiconductor structure 5700A, the second semiconductor structure 5700B, the third semiconductor structure 5800A, and the fourth semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit, the second semiconductor structure 5700B may include a second peripheral circuit, the third semiconductor structure 5800A may include a first memory cell array, and the fourth semiconductor structure 5800B may include a second memory cell array.

The first semiconductor structure 5700A may include a first substrate 5710, a first transistor 5720, a first interlayer insulating layer 5730, a first interconnection structure 5740, and a first bonding pad 5750. The first transistor 5720 may be included in the first peripheral circuit. The first peripheral circuit may include a row decoder, a page buffer, an input/output circuit, a logic circuit, and the like. The first interconnection structure 5740 may be disposed in the first interlayer insulating layer 5730 and may include a via, a wiring line, and the like. The first bonding pad 5750 may be disposed at a first bonding interface 5007 and may be electrically connected to the first peripheral circuit through the first interconnection structure 5740.

The second semiconductor structure 5700B may include a second substrate 5711, a second transistor 5721, a second interlayer insulating layer 5731, a second interconnection structure 5741, and a second bonding pad 5751. The second transistor 5721 may be included in the second peripheral circuit. The second peripheral circuit may include a row decoder, a page buffer, an input/output circuit, a logic circuit, and the like. The second interconnection structure 5741 may be disposed in the second interlayer insulating layer 5731 and may include a via, a wiring line, and the like. The second bonding pad 5751 may be disposed at a second bonding interface 5008 and may be electrically connected to the second peripheral circuit through the second interconnection structure 5741.

The third semiconductor structure 5800A may include a first gate structure 5810, a first channel structure 5820, a first source structure 5830, a third interlayer insulating layer 5840, a third interconnection structure 5850, a third bonding pad 5860, and a first contact plug 5870. The first gate structure 5810 may include first gate lines 5811 alternately stacked with first insulating layers 5812. The first source structure 5830 may be disposed over or under the first gate structure 5810. The first channel structure 5820 may include a first channel layer 5821, a first memory layer 5822, and/or a first insulating core 5823. The first channel layer 5821 may extend through the first gate structure 5810 and may be connected to the first source structure 5830. The third interconnection structure 5850 may be disposed in the third interlayer insulating layer 5840 and may include a via, a wiring line, and the like. For example, the third interconnection structure 5850 may include a bitline 5852. The third bonding pad 5860 may be disposed at the first bonding interface 5007 and may be electrically connected to the first memory cell array through the third interconnection structure 5850.

The fourth semiconductor structure 5800B may include a second gate structure 5816, a second channel structure 5826, a second source structure 5831, a fourth interlayer insulating layer 5841, a fourth interconnection structure 5851, a fourth bonding pad 5861, and a second contact plug 5880. The second gate structure 5816 may include second gate lines 5817 alternately stacked with second insulating layer 5818. The second source structure 5831 may be disposed over or under the second gate structure 5816. The second source structure 5831 may be electrically connected to the first source structure 5830 and driven in common with the first source structure 5830. The second channel structure 5826 may include a second channel layer 5827, a second memory layer 5828, and/or a second insulating core 5829. The second channel layer 5827 may extend through the second gate structure 5816 and may be connected to the second source structure 5831. The fourth interconnection structure 5851 may be disposed in the fourth interlayer insulating layer 5841 and may include a via, a wiring line, and the like. For example, the fourth interconnection structure 5851 may include a bitline 5853. The fourth bonding pad 5861 may be disposed at the second bonding interface 5008 and may be electrically connected to the second memory cell array through the fourth interconnection structure 5851.

The first bonding pad 5750 may be electrically connected to the third bonding pad 5860 at the first bonding interface 5007, and the first memory cell array may be electrically connected to the first peripheral circuit through the first bonding pad 5750 and the third bonding pad 5860. The second bonding pad 5751 may be electrically connected to the fourth bonding pad 5861 at the second bonding interface 5008, and the second memory cell array may be electrically connected to the second peripheral circuit through the second bonding pad 5751 and the fourth bonding pad 5861. The first source structure 5830 may be bonded to the second source structure 5831 at a third bonding interface 5009. Thus, the first memory cell array may be electrically connected to the second memory cell array.

The first contact plug 5870 may extend through the third interlayer insulating layer 5840 or a dummy stack, and the second contact plug 5880 may extend through the fourth interlayer insulating layer 5841 or a dummy stack. The first contact plug 5870 may be connected to the second contact plug 5880, and the first peripheral circuit may be connected to the second peripheral circuit through the first bonding pad 5750, the third bonding pad 5860, the first contact plug 5870, the second contact plug 5880, the fourth bonding pad 5861, and the second bonding pad 5751.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the first memory cell array, a third wafer including the second peripheral circuit, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

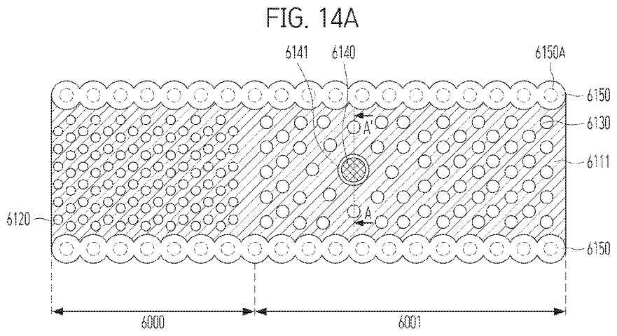

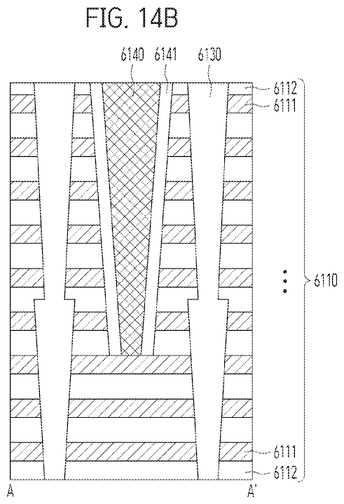

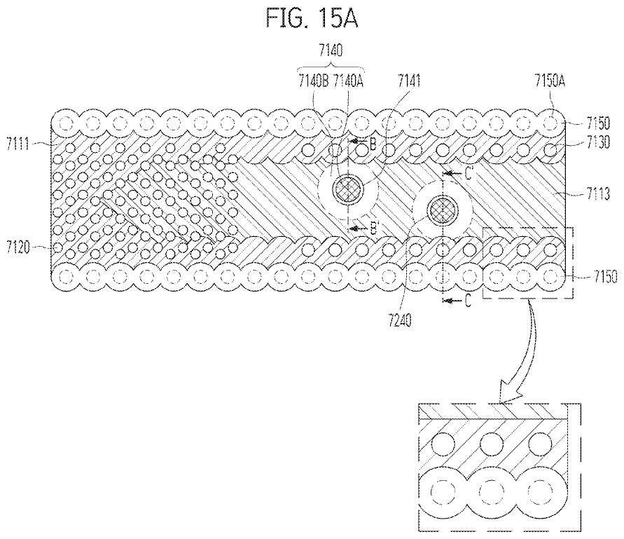

FIGS. 14A and 14B are diagrams illustrating the structure of a semiconductor device in accordance with an embodiment. FIG. 14B is a cross-sectional view taken along line A A′ of FIG. 14A.

Referring to FIGS. 14A and 14B, the semiconductor device may include a gate structure 6110, channel structures 6120, supports 6130, a contact plug 6140, an insulating spacer 6141, and slit structures 6150. The term “slit structure” in the present disclosure does not indicate that a slit has a structure but rather is so named because the process of forming a slit structure utilizes a slit. The slit structures 6150 may extend in one direction, and the gate structure 6110 may be disposed between the slit structures 6150. Each of the slit structures 6150 may include an insulating material, a semiconductor material, and/or a conductive material. The gate structure 6110 may include gate lines 6111 alternately stacked with insulating layers 6112. The gate lines may be word lines, a source select line, or a drain select line.

The gate structure 6110 may include a cell region 6111 and a contact region 6112. The channel structures 6120 may be disposed in the cell region 6111 of the gate structure 6110. The channel structures 6120 may extend in a vertical direction through the gate structure 6110, and memory cells may be stacked along the channel structures 6120. The supports 6130 and the contact plug 6140 may be disposed in the contact region 6112 of the gate structure 6110. The supports 6130 may extend in the vertical direction through the gate structure 6110. Each of the supports 6130 may include an insulating material, a semiconductor material, and/or a conductive material.

The contact plug 6140 may be electrically connected to a gate line 6111. For example, the contact region 6112 of the gate structure 6110 may include a staircase structure (not shown), and the contact plug 6140 may be electrically connected to the gate line through the staircase structure. For example, the gate structure 6110 may not include the staircase structure, and the contact plug 6140 may extend through the gate structure 6110 and be electrically connected to the gate line. The insulating spacer 6141 may surround a sidewall of the contact plug 6140.

Processes of manufacturing the channel structures 6120, the supports 6130, and the slit structures 6150 may be performed simultaneously. Holes that form the channel structures 6120, the supports 6130, and the slit structures 6150 may be simultaneously formed, and sacrificial layers may be formed in the holes. The sacrificial layers are removed to form holes, and structures are formed within the holes. For example, holes 6150A arranged in a row may be formed in a region where the slit structure is to be formed. A slit may be formed by expanding the holes 6150A thereby connecting the holes 6150A together, and the slit structure 6150 may be formed in the slit. In such an example, the sidewalls of the slit structure 6150 may include irregularities or uneven surfaces.

The semiconductor device may be manufactured using a replacement process. For example, a stack may be formed including sacrificial layers alternately stacked with insulating layers, and a contact hole may be formed extending through the stack. A sacrificial pattern may be formed in the contact hole, and the sacrificial layers may be replaced with the gate lines 6111 to form the gate structure 6110. The sacrificial pattern may be removed, and the insulating spacer 6141 may be formed on sidewalls of the stack exposed by the contact hole. The contact plug 6140 may be formed within the insulating spacer 6141 formed in the contact hole.

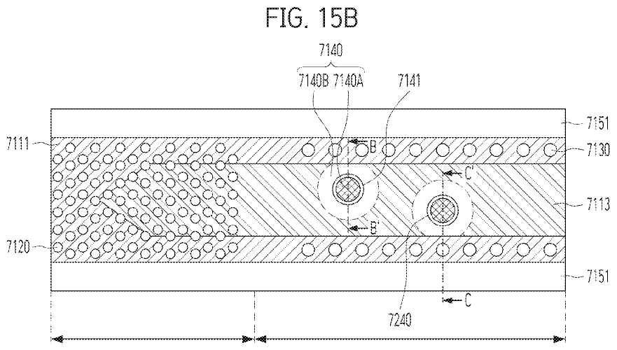

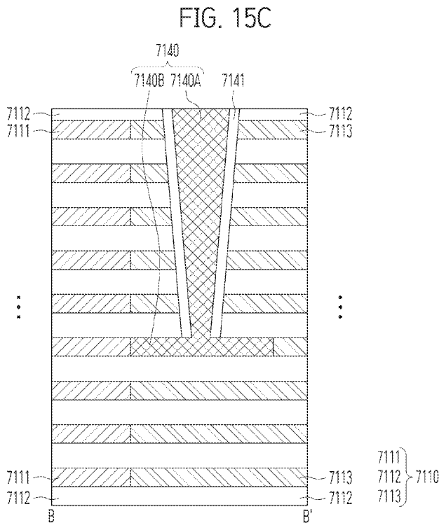

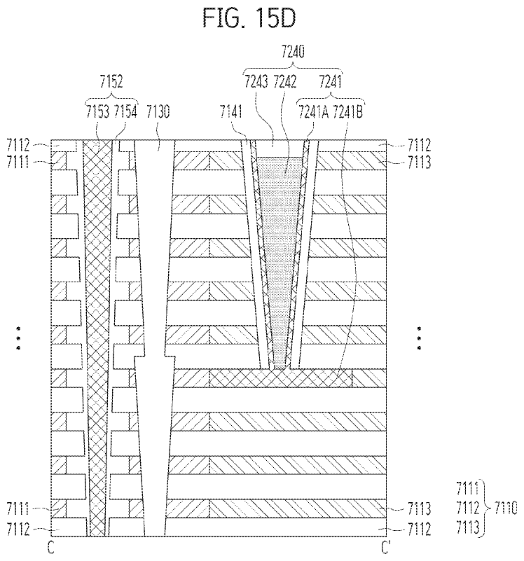

FIGS. 15A to 15D are diagrams illustrating the structure of a semiconductor device in accordance with an embodiment. FIG. 15C is a cross-sectional view taken along line B-B′ of FIG. 15A. FIG. 15D is a modified example of FIG. 15C and is a cross-sectional view taken along line C-C′ of FIG. 15A.

Referring to FIGS. 15A and 15B, the semiconductor device may include a gate structure 7110, channel structures 7120, supports 7130, a contact plug 7140, an insulating spacer 7141, and slit structures 7150 and 7151.

The slit structures 7150 may extend in one direction, and the gate structure 7110 may be disposed between the slit structures 7150. Referring to FIG. 15A, the slit structures 7150 may be formed within a slit defined by extending and connecting holes 7150A arranged in a row, and may have irregularities on their sidewalls. Referring to FIG. 15B, the slit structure 7151 may be formed within a line-shaped slit, and the sidewalls may have a linear shape without irregularities. Each of the slit structures 7150 and 7151 may include an insulating material, a semiconductor material, and/or a conductive material.

The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113. The gate line 7111 may surround the dielectric layer 7113. The interface between the gate line 7111 and the dielectric layer 7113 may be uneven or corrugated, or may have a linear shape. The supports 7130 may be disposed between the dielectric layers 7113 and the slit structures 7150, and may extend through the gate lines 7111 and the insulating layers 7112.

The contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level corresponding to a dielectric layer 7113 and may extend in a horizontal direction to be electrically connected to the gate line 7111. The insulating spacer 7141 may surround the pillar portion 7140A. The semiconductor device may include a plurality of contact plugs 7140, and each of the plurality of contact plugs 7140 may extend to a different depth and be connected to a different gate line 7111. In an embodiment, the pillar 7120A and the contact 7120B are formed as a single unified structure, for example, formed in one process using the same material. Alternatively, the pillar 7120A and the contact 7120B may be formed separately and connected together.

Referring to FIGS. 15A and 15D, the semiconductor device may include a gate structure 7110, channel structures 7120, a contact plug 7240, an insulating spacer 7141, supports 7130, and a slit structure 7150. The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130 may extend through the gate lines 7111 that are alternately stacked with the insulating layers 7112. The supports 7130 may each include an insulating material, a semiconductor material, and/or a conductive material. The slit structure 7150 may include a structure formed in a slit used as a passage for a replacement process and may extend between adjacent gate structures 7110. For example, the slit structure 7150 may include a conductive layer 7151 and an insulating spacer 7152 surrounding sidewalls of the conductive layer 7151. The insulating spacer 7152 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor device may include a plurality of contact plugs 7240, and each of the plurality of contact plugs 7240 may extend to a different depth and is connected to a different gate line 7111.

The semiconductor device may be manufactured using a replacement process. For example, the gate structure 7110 may be formed by forming a stack including sacrificial layers alternately stacked with the insulating layers 7112 and replacing the sacrificial layers with the gate lines 7111 through the slit. The stack may include a cell region and a contact region, and the sacrificial layers may remain in a region of the contact region spaced apart from the slit. The dielectric layers 7113 of the gate structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

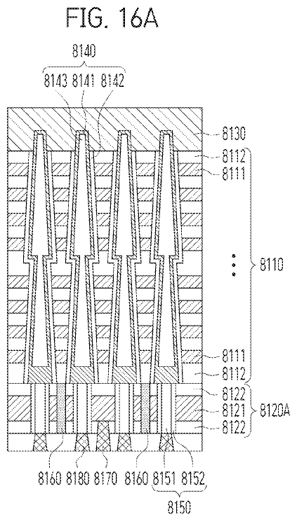

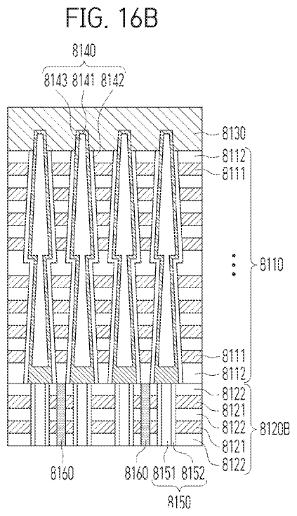

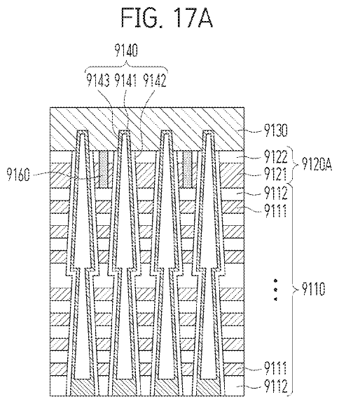

FIGS. 16A and 16B are diagrams illustrating the structure of a semiconductor device in accordance with an embodiment.

Referring to FIGS. 16A and 16B, the semiconductor device may include a first gate structure 8110, a second gate structure 8120A or 8120B, a source structure 8130, a first channel structure 8140, a second channel structure 8150, and an isolation insulating structure 8160. The first gate structure 8110 may include first gate lines 8111 alternately stacked with first insulating layers 8112. The first gate lines 8111 may be word lines or a source select line. The source structure 8130 may be disposed over the first gate structure 8110.

The second gate structure 8120A or 8120B may be disposed under the first gate structure 8110. Referring to FIG. 16A, the second gate structure 8120A may include a second gate line 8121 alternately stacked with second insulating layers 8122. The first contact plug 8170 may be connected to the second gate line 8121, and the second contact plugs 8180 may be connected to the second channel structures 8150. The first contact plug 8170 and the second contact plugs 8180 may be located in a cell region. Referring to FIG. 16B, the second gate structure 8120B may include second gate lines 8121 alternately stacked with second insulating layers 8122. Contact plugs may be connected to respective ones of the second gate lines 8121, and the contact plugs may be located in a contact region.

The second gate line 8121 may be a drain select line. The second gate line 8121 may be thicker than the first gate line 8111 or have substantially the same thickness as the first gate line 8111. The second gate line 8121 may include a different material from the first gate line 8111. For example, the first gate line 8111 may include metal such as tungsten (W) or molybdenum (Mo), and the second gate line 8121 may include polysilicon. Consecutive second gate lines 8121 disposed at the same level may be insulated by an isolation insulating structure 8160. In a plan view, the isolation insulating structures 8160 may extend in a line or a wave or zigzag shape.

The first channel structures 8140 may extend through the first gate structure 8110. The first channel structure 8140 may include a first channel layer 8141, a memory layer 8142, and/or an insulating core 8143. The second channel structures 8150 may extend through the second gate structure 8120A or 8120B and may be connected to the first channel structures 8140. The second channel structure 8150 may include a second channel layer 8151 and a gate insulating layer 8152.

The first gate structure 8110 and the second gate structure 8120A or 8120B may be formed by separate processes. For example, the first gate structure 8110 may be formed by forming a stack including sacrificial layers alternately stacked with the first insulating layers 8112 and replacing the sacrificial layers with the first gate lines 8111. The second gate structure 8120A or 8120B may be formed on the first gate structure 8110. At least one conductive layer and the second insulating layers 8122 may be formed, and the second gate lines 8121 and trenches between the second gate lines 8121 may be formed by etching at least one conductive layer and the second insulating layers 8122. The isolation insulating structures 8160 may be formed in the trenches.

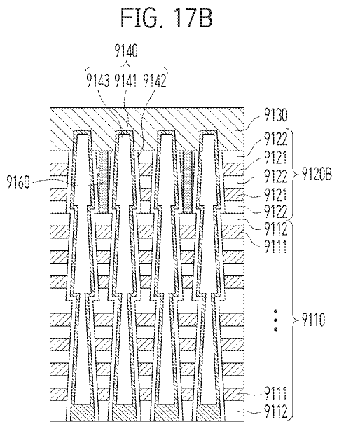

FIGS. 17A and 17B are diagrams illustrating the structure of a semiconductor device in accordance with an embodiment.

Referring to FIGS. 17A and 17B, a semiconductor device may include a first gate structure 9110, a second gate structure 9120A or 9120B, a source structure 9130, a channel structure 9140, and an isolation insulating structure 9160. The first gate structure 9110 may include first gate lines 9111 alternately stacked with first insulating layers 9112. The first gate lines 9111 may be word lines or a drain select line. The source structure 9130 may be disposed over the first gate structure 9110.

The second gate structure 9120A or 9120B may be disposed between the first gate structure 9110 and the source structure 9130. Referring to FIG. 17A, the second gate structure 9120A may include a second gate line 9121 alternately stacked with second insulating layers 9122. Referring to FIG. 17B, the second gate structure 9120B may include second gate lines 9121 alternately stacked with second insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape.

The channel structures 9140 may extend through the first gate structure 9110 and the second gate structure 9120A or 9120B. The channel structure 9140 may include a channel layer 9141, a memory layer 9142, and/or an insulating core 9143.

The first gate structure 9110 and the second gate structure 9120A or 9120B may be formed by separate processes. For example, the second gate structure 9120A or 9120B may be formed on a substrate. At least one conductive layer and the second insulating layers 9122 may be formed, and the second gate lines 9121 and trenches between the second gate lines 9121 may be formed by etching at least one conductive layer and the second insulating layers 9122. The isolation insulating structures 9160 may be formed in the trenches. The first gate structure 9110 may be formed by forming a stack including sacrificial layers alternately stacked with the first insulating layers 9112 and replacing the sacrificial layers with the first gate lines 9111. A wafer bonding process may be performed, the substrate may be removed, and the source structure 9130 may be formed. In another example, the second gate structure 9120A or 9120B including at least one conductive layer and the second insulating layers 9122 may be formed on a substrate. The first gate structure 9110 may be formed by forming a stack including sacrificial layers alternately stacked with the first insulating layers 9112 and replacing the sacrificial layers with the first gate lines 9111. A wafer bonding process may be performed, and a rear surface of the second gate structure 9120A or 9120B may be exposed by removing the substrate. The second gate lines 9121 and trenches between the second gate lines 9121 may be formed by etching at least one conductive layer and the second insulating layers 9122, and the isolation insulating structures 9160 may be formed in the trenches. The source structure 9130 may be formed.

What is claimed is:

1. A semiconductor device comprising:
a source layer having a groove in an upper surface thereof;
a conductive pattern disposed in the groove;
a stack structure disposed over the source layer and the conductive pattern, the stack structure comprising at least one first select line, a plurality of word lines and at least one second select line;
a channel layer extending through the stack structure, the channel layer being in contact with the source layer; and
a source pick-up line extending through the stack structure and the conductive pattern to contact the source layer,
wherein a vertical length of the channel layer is greater than a vertical length of the source pick-up line.

2. The semiconductor device of claim 1, wherein the source layer comprises:
a first source layer; and
a second source layer disposed on the first source layer, the second source layer including the groove.

3. The semiconductor device of claim 2,
wherein a bottom of the channel layer is disposed between a top surface and a bottom surface of the first source layer, and
wherein a bottom of the source pick-up line is disposed between a top surface and a bottom surface of the second source layer.

4. The semiconductor device of claim 1, wherein a width of the source pick-up line is smaller than a width of the conductive pattern.

5. The semiconductor device of claim 1,
wherein the channel layer extends into the source layer by passing through a flat portion of the upper surface of the source layer, and
wherein the source pick-up line contacts the source layer within the groove.

6. The semiconductor device of claim 1, further comprising:
an insulative spacer surrounding a sidewall of the source pick-up line and disposed between the source pick-up line and the conductive pattern.

7. A semiconductor device comprising:
a source layer having a groove in an upper surface thereof;
a stack structure disposed over the source layer, wherein the stack structure includes at least one first select line, word lines and at least one second select line;
a channel layer extending through the stack structure, the channel layer being in contact with the source layer; and
a source pick-up line extending through the stack structure and into the groove to contact the source layer,
wherein the channel layer has a greater height than the source pick-up line.

8. The semiconductor device of claim 7, wherein the source layer comprises:
a first source layer; and
a second source layer disposed on the first source layer, the second source layer including the groove.

9. The semiconductor device of claim 8,
wherein a bottom of the channel layer is disposed between a top surface and a bottom surface of the first source layer, and
wherein a bottom of the source pick-up line is disposed between a top surface and a bottom surface of the second source layer.

10. The semiconductor device of claim 7, wherein a width of the source pick-up line is smaller than a width of the conductive pattern.

11. The semiconductor device of claim 7,
wherein the channel layer extends into the source layer by passing through a flat portion of the upper surface of the source layer, and
wherein the source pick-up line contacts the source layer within the groove.

12. The semiconductor device of claim 7, wherein the source pick-up line comprises:
a first portion extending through the stack structure; and
a second portion disposed in the groove.

13. The semiconductor device of claim 12, wherein a width of the second portion is greater than a width of the first portion.
